(19) United States
(12) Patent Application Publication
(10) Pub. No.: US 2024/0203868 A1
(43) Pub. Date: Jun. 20, 2024

(54) SERIAL DIRECTED SELF-ASSEMBLY (DSA) PROCESSES FOR FORMING METAL LAYER WITH CUT

(71) Applicant: Intel Corporation, Santa Clara, CA (US)

(72) Inventors: Gurpreet Singh, Portland, OR (US); Manish Chandhok, Beaverton, OR (US); David Nathan Shykind, Buxton, OR (US); Richard E. Schenker, Portland, OR (US); Florian Gstrein, Portland, OR (US); Eungnak Han, Portland, OR (US); Nafees Aminul Kabir, Hillsboro, OR (US); Sean Michael Pursel, Hillsboro, OR (US); Nityan Labros Nair, Portland, OR (US); Robert Seidel, Hillsboro, OR (US)

(73) Assignee: Intel Corporation, Santa Clara, CA (US)

(21) Appl. No.: 18/066,301

(22) Filed: Dec. 15, 2022

(51) Int. Cl. H01L 23/522; H01L 21/768

(52) U.S. Cl. CPC H01L 23/5226; H01L 21/76802; H01L 21/76879

(57) ABSTRACT

Metal lines are formed through serial DSA processes. A first DSA process may define a pattern of first hard masks. First metal lines are fabricated based on the first hard masks. A metal cut crossing one or more first metal lines may be formed. A width of the metal cut is no greater than a pitch of the first metal lines. After the metal cut is formed, a second DSA process is performed to define a pattern of second hard masks. Edges of a second hard mask may align with edges of a first metal line. An insulator may be formed around a second hard mask to form an insulative structure. An axis of the insulative structure may be aligned with an axis of a first metal line. Second metal lines are formed based on the second hard masks and have a greater height than the first metal lines.

### BACKGROUND

IC (integrated circuit) fabrication usually includes two stages. The first stage is referred to as the front end of line (FEOL). The second stage is referred to as the back end of line (BEOL). In the FEOL, individual components (e.g., transistor, capacitors, resistors, etc.) can be patterned in a wafer. In the BEOL, metal layers, vias, and insulating layers can be formed to get the individual components interconnected. The BEOL usually starts with forming the first metal layer on the wafer. The first metal layer is often called M0. More metal layers can be formed on top of M0, and these metal layers are often called M1, M2, and so on.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIGS. 1A and 1B illustrates an IC device comprising an FEOL section and a BEOL section, according to some embodiments of the disclosure.

FIGS. 2A-2D illustrate an example DSA process for forming hard masks over a conductive layer, according to some embodiments of the disclosure.

FIGS. 3A-3D illustrate another example DSA process for forming hard masks over a conductive layer, according to some embodiments of the disclosure.

FIGS. 4A-4D illustrates a process of forming metal lines, according to some embodiments of the disclosure.

FIGS. 5A-5D illustrate an example DSA process for forming hard masks over a layer, according to some embodiments of the disclosure.

FIGS. 6A-6D illustrate another example DSA process for forming hard masks over a layer, according to some embodiments of the disclosure.

FIGS. 7A-7D illustrate yet another example DSA process for forming hard masks over a layer, according to some embodiments of the disclosure.

FIGS. 8A-8D illustrate a process of forming additional metal lines for a metal layer, according to some embodiments of the disclosure.

FIGS. 9A-9B are top views of a wafer and dies that may include metal lines formed through serial DSA processes, according to some embodiments of the disclosure.

FIG. 10 is a side, cross-sectional view of an example IC package that may include one or more IC devices having metal lines formed through serial DSA processes, according to some embodiments of the disclosure.

FIG. 11 is a cross-sectional side view of an IC device assembly that may include components having one or more IC devices implementing metal lines formed through serial DSA processes, according to some embodiments of the disclosure.

FIG. 12 is a block diagram of an example computing device that may include one or more components with metal lines formed through serial DSA processes, according to some embodiments of the disclosure.

### DETAILED DESCRIPTION

The systems, methods, and devices of this disclosure each have several innovative aspects, no single one of which is solely responsible for all the desirable attributes disclosed herein. Details of one or more implementations of the subject matter described in this specification are set forth in the description below and the accompanying drawings.

Continued scaling of transistors and design cell height leads to narrow BEOL metal lines. This creates a challenge for metal patterning, via landing, or edge placement error control and the need to ensure low resistance of metal lines and vias. Taking metal pitch for example, metal pitch (also referred to as “pitch”) is the center-to-center distance between two adjacent metal lines. The two adjacent metal lines may be metal lines that are located right next to each other without another metal line in between. Metal pitches are getting tighter and tighter. Metal layers that are close to FEOL devices (e.g., M0, M1, M2, etc.) may have metal pitches below 24 nanometers (nm). Tight metal pitch can require tight end-to-end (ETE) distance of metal cut. Metal cut (also referred to as “line end,” “metal plug,” “plug,” or “cut”) is a non-conductive structure (e.g., insulative structure) between metal lines. For a metal pitch of around 24 nm, the ETE distance of the metal cut may need to be around 20 nm or even less. When patterning small metal cuts with small metal pitches, several challenges can present especially when the metal pitches are around 24 nm or even less. Also, with the decreasing size of metal lines, surface roughness of metal lines becomes more important. However, currently available technologies for fabricating metal lines fail to provide better surface roughness. Therefore, improved technology for BEOL metal lines is needed.

Embodiments of the present disclosure may improve on at least some of the challenges and issues described above by providing metal lines formed through serial DSA processes. Serial DSA processes may include a first DSA process and a second DSA process performed after the first DSA process. In an example of producing a metal layer, the first DSA process may define a pattern of first hard masks over a metal layer based on self-assembly of a diblock copolymer. The first hard masks are separated from each other with openings in between. First metal lines can be formed based on the first hard masks, e.g., by removing portions of the metal layer that are over the openings. The portions of the metal layer that are over the hard masks may be kept and constitutes the first metal lines. An electrical insulator may be added to surround the first metal lines at least partially so that the first metal lines are insulated from each other. The first hard masks may be removed after the first metal lines are formed. A metal cut may be fabricated by forming an opening by removing a portion of at least one first metal line and filling the opening with an electrical insulator. The metal cut may cross one or more first metal lines. For each of the one or more first metal lines, the metal cut may function as an insulative structure that insulates a portion of the first metal line from another portion of the first metal line.

A preliminary metal layer, which includes the first metal lines, the electrical insulator at least partially surrounding the first metal lines, and the metal cut, is therefore formed. The pitch of the preliminary metal layer is the center-to-center distance between two adjacent first metal lines and can be larger than the final pitch of the metal layer. In some embodiments, the pitch of the preliminary metal layer may be about two times the pitch of the metal layer. The pitch of the preliminary metal layer may be equal to or greater than a width of the metal cut. A height of the metal cut may be the same or substantially the same as the height of a first metal line. The length of the metal cut can vary, depending on how many metal lines it crosses.

The second DSA process may be performed over the preliminary metal layer. The second DSA process may define a pattern of second hard masks over the preliminary metal layer based on self-assembly of a diblock copolymer. The second hard masks are separated from each other with openings in between. Each second hard mask may be over a first metal line. In some embodiments, one or more edges of a second hard mask may be aligned with corresponding edges of the first metal line over which the second hard mask is arranged. An insulator may be deposited onto the layer to surround each second hard mask at least partially. The insulator and each second hard masks constitute an insulative structure. A portion of the insulative structure is over the first metal line in a direction. An axis of the insulative structure in the direction may be aligned with an axis of the first metal line in the direction. A length of the insulative structure in a direction perpendicular to the axis may be greater than a length of the first metal line in the direction.

An opening between two adjacent second hard masks is over a portion of the electrical insulator in the layer. New openings can be formed by removing the portions of the electrical insulator that are over the openings. One or more metals can be provided into the new openings to form second metal lines. The first metal lines and the second metal lines constitute the metal layer. The axis of each second metal line may be in parallel with the axis of each first metal line. The height of a second metal line along the axis is greater than the height of a first metal line. In some embodiments, the height of the second metal line may be the same or similar as the sum of the height of the first metal line and the height of the insulative structure over the first metal line. One or more dimensions of a second metal line may be the same or similar as corresponding dimensions of a first metal line. A second metal line is between two adjacent first metal lines. Due to the addition of the second metal lines, the pitch of the metal layer is reduced. The pitch of the metal layer (e.g., the center-to-center distance between a pair of adjacent first metal line and second metal line) may be half of the pitch of the preliminary metal layer that does not include the second metal lines. In some embodiments, the pitch of the metal layer may be no greater than 20 nm.

Compared with conventionally available technologies, the present disclosure provides a more advantageous method of fabricating metal layers, especially metal layers closer to FEOL devices. The present disclosure facilitates formation of metal cuts with a larger pitch, i.e., the pitch between two adjacent first metal lines. The larger pitch can provide more space to form metal cuts and therefore, the challenges of forming metal cuts with a tight pitch can be avoided. Also, taller metal lines (i.e., the second metal lines) can be formed with the present disclosure, which can facilitate production of taller memory devices, such as taller static random-access memory (SRAM) with lower resistance. Further, the self-assembly of diblock copolymers can facilitate good alignment of the hard masks and metal lines, which can result in smoother edges of the metal lines compared with conventional available technologies. The line edge roughness of metal lines in the present disclosure may be between about 1.1 nm and 1.5 nm. In an example, the line edge roughness of metal lines in the present disclosure may be about 1.2 nm. That is lower than line edge roughness of conventional available metal lines, which can be above 1.7 nm. The lower line edge roughness can result in lower resistance, higher yield, better metal fill, better reliability, and therefore, provides better performance of the metal lines.

It should be noted that, in some settings, the term “nanoribbon” has been used to describe an elongated semiconductor structure that has a substantially rectangular transverse cross-section (e.g., a cross-section in a plane perpendicular to the longitudinal axis of the structure), while the term “nanowire” has been used to describe a similar structure but with a substantially circular or square transverse cross-sections. In the following, a single term “nanoribbon” is used to describe an elongated semiconductor structure independent of the shape of the transverse cross-section. Thus, as used herein, the term “nanoribbon” is used to cover elongated semiconductor structures that have substantially rectangular transverse cross-sections (possibly with rounded corners), elongated semiconductor structures that have substantially square transverse cross-sections (possibly with rounded corners), elongated semiconductor structures that have substantially circular or elliptical/oval transverse cross-sections, as well as elongated semiconductor structures that have any polygonal transverse cross-sections. A longitudinal axis of a structure refers to a line (e.g., an imaginary line) that runs down the center of the structure in a direction perpendicular to a transverse cross-section of the structure.

In the following, some descriptions may refer to a particular source or drain (S/D) region or contact being either a source region/contact or a drain region/contact. However, unless specified otherwise, which region/contact of a transistor or diode is considered to be a source region/contact and which region/contact is considered to be a drain region/contact is not important because, as is common in the field of FETs, designations of source and drain are often interchangeable. Therefore, descriptions of some illustrative embodiments of the source and drain regions/contacts provided herein are applicable to embodiments where the designation of source and drain regions/contacts may be reversed.

As used herein, the term “metal layer” may refer to a layer above a substrate that includes electrically conductive interconnect structures for providing electrical connectivity between different IC components. Metal layers described herein may also be referred to as “interconnect layers” to clearly indicate that these layers include electrically conductive interconnect structures which may, but do not have to be, metal.

The systems, methods and devices of this disclosure each have several innovative aspects, no single one of which is solely responsible for all of the desirable attributes disclosed herein. Details of one or more implementations of the subject matter described in this specification are set forth in the description below and the accompanying drawings.

In the following detailed description, various aspects of the illustrative implementations may be described using terms commonly employed by those skilled in the art to convey the substance of their work to others skilled in the art. For example, the term “connected” means a direct electrical or magnetic connection between the things that are connected, without any intermediary devices, while the term “coupled” means either a direct electrical or magnetic connection between the things that are connected, or an indirect connection through one or more passive or active intermediary devices. The term “circuit” means one or more passive and/or active components that are arranged to cooperate with one another to provide a desired function. If used, the terms “oxide,” “carbide,” “nitride,” etc. refer to compounds containing, respectively, oxygen, carbon, nitrogen, etc., the term “high-k dielectric” refers to a material having a higher dielectric constant (k) than silicon oxide, while the term “low-k dielectric” refers to a material having a lower k than silicon oxide. The terms “substantially,” “close,” “approximately,” “near,” and “about,” generally refer to being within +/−10%, e.g., within +/−5% or within +/−2%, of a target value based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−8% of a target value, e.g., within +/−5% of a target value or within +/−2% of a target value, based on the context of a particular value as described herein or as known in the art. Also, the term “or” refers to an inclusive “or” and not to an exclusive “or.”

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening layers.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. As used herein, the notation “A/B/C” means (A), (B), and/or (C).

The description may use the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

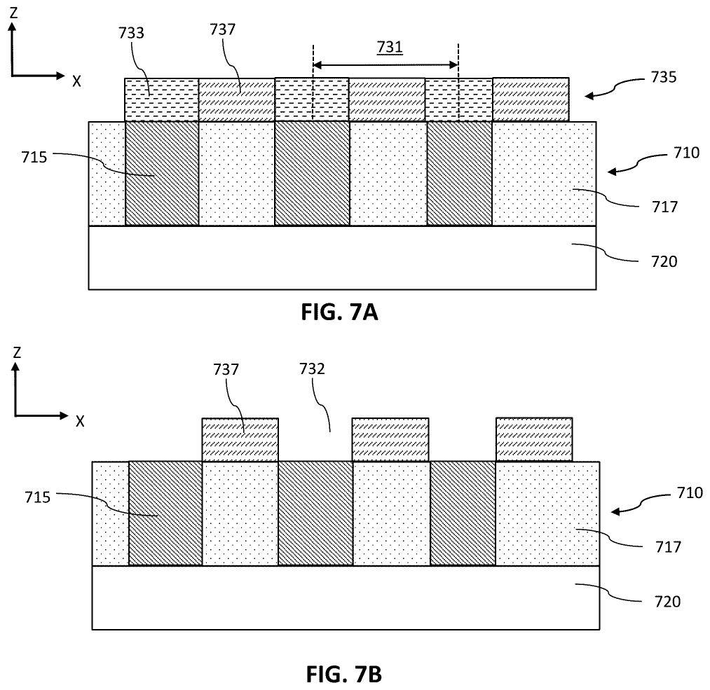

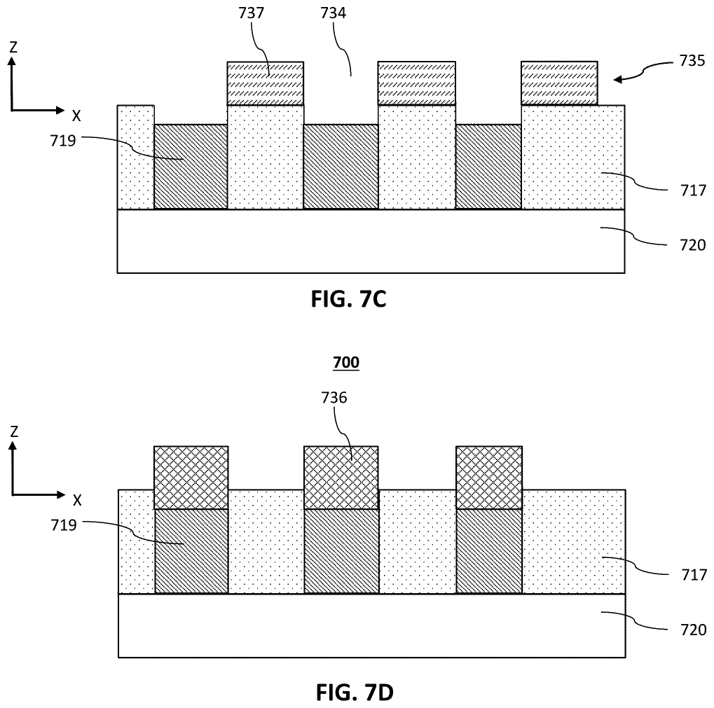

In the following detailed description, reference is made to the accompanying drawings that form a part hereof, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense. For convenience, if a collection of drawings designated with different letters are present, e.g., FIGS. 7A-7B, such a collection may be referred to herein without the letters, e.g., as “FIG. 7.”

In the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross-section of a device to detect the shape and the location of various device elements described herein using, e.g., Physical Failure Analysis (PFA) would allow determination of presence of metal lines formed through serial DSA processes as described herein.

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

Various metal lines formed through serial DSA processes as described herein may be implemented in, or associated with, one or more components associated with an IC or/and may be implemented between various such components. In various embodiments, components associated with an IC include, for example, transistors, diodes, power sources, resistors, capacitors, inductors, sensors, transceivers, receivers, antennas, etc. Components associated with an IC may include those that are mounted on IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

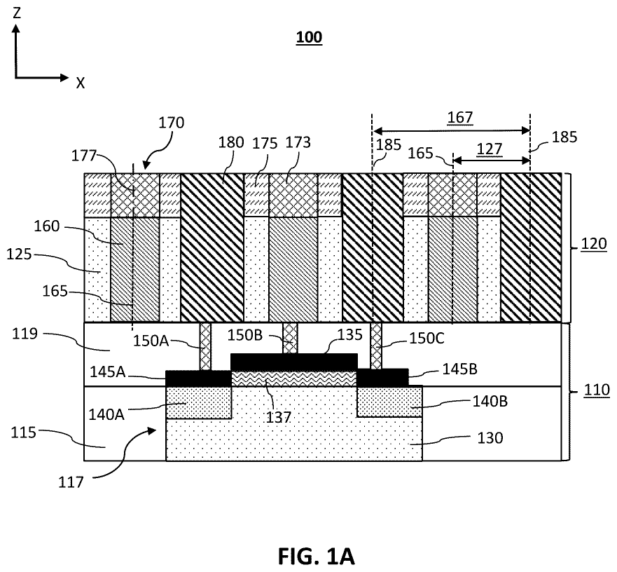

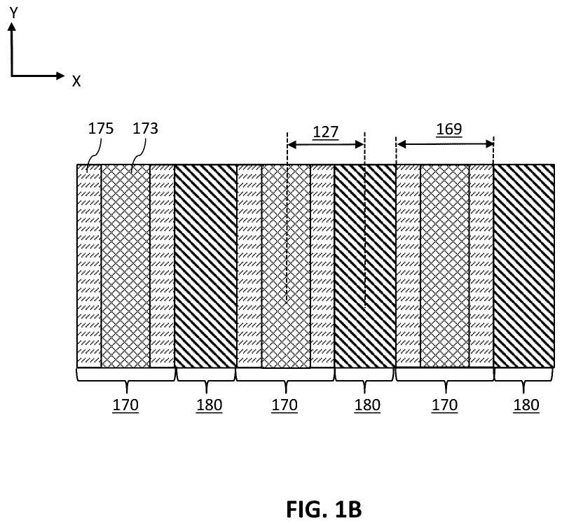

FIGS. 1A and 1B illustrates an IC device 100 comprising an FEOL section 110 and a BEOL section 120, according to some embodiments of the disclosure. FIG. 1A shows a cross-sectional side view of the IC device 100. FIG. 1B shows a top view of the IC device 100. As shown in FIG. 1A, the FEOL section 110 includes a support structure 115, a transistor 117, and an insulative structure 119. The BEOL section 120 includes a metal layer including three metal lines 160 (individually referred to as “metal line 160”) and three metal lines 180 (individually referred to as “metal line 180”), an electrical insulator 125, and three insulative structures 170 (individually referred to as “insulative structure 170”). In other embodiments, the IC device 100 may include fewer, more, or different components. For instance, the FEOL section 110 may include more transistors, or other semiconductor devices not shown in FIG. 1. Also, the BEOL section 120 may include one or more other metal layers, which may be coupled to the metal layer. The metal layer may include a different number of metal lines 160 or 180. The BEOL section 120 may include a different number of insulative structures 170.

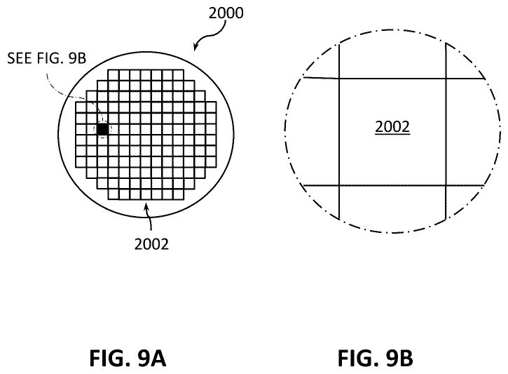

The support structure 115 may be any suitable structure, such as a substrate, a die, a wafer, or a chip, based on which the transistor 117 can be built. The support structure 115 may, e.g., be the wafer 2000 of FIG. 9A, discussed below, and may be, or be included in, a die, e.g., the singulated die 2002 of FIG. 9B, discussed below. In some embodiments, the support structure 115 may be a semiconductor substrate composed of semiconductor material systems including, for example, N-type or P-type materials systems, and, in some embodiments, the channel region 130, described herein, may be a part of the support structure 115. In some embodiments, the semiconductor substrate may be a crystalline substrate formed using a bulk silicon or a silicon-on-insulator substructure. In other embodiments, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V, group II-VI, or group IV materials. In some embodiments, the substrate may be non-crystalline. In some embodiments, the support structure may be a printed circuit board (PCB) substrate. One or more transistors, such as the transistor 117 may be built on the support structure 115.

Although a few examples of materials from which the support structure 115 may be formed are described here, any material that may serve as a foundation upon which an IC may be built falls within the spirit and scope of the present disclosure. In various embodiments, the support structure 115 may include any such substrate, possibly with some layers and/or devices already formed thereon, not specifically shown in the present figures. As used herein, the term “support” does not necessarily mean that it provides mechanical support for the IC devices/structures (e.g., transistors, capacitors, interconnects, and so on) built thereon. For example, some other structure (e.g., a carrier substrate or a package substrate) may provide such mechanical support and the support structure 115 may provide material “support” in that, e.g., the IC devices/structures described herein are build based on the semiconductor materials of the support structure 115. However, in some embodiments, the support structure 115 may provide mechanical support.

The transistor 117 may be a field-effect transistor (FET), such as metal-oxide-semiconductor FET (MOSFET), tunnel FET (TFET), fin-based transistor (e.g., FinFET), nanoribbon-based transistor, nanowire-based transistor, gate-all-around (GAA) transistor, other types of FET, or a combination of both. A transistor 117 includes a semiconductor structure that includes a channel region 130, a source region 140A, and a drain region 140B. The semiconductor structure of the transistor 117 may be at least partially in the support structure 115. The support structure 115 may include a semiconductor material, from which at least a portion of the semiconductor structure is formed. The semiconductor structure of the transistor 117 (or a portion of the semiconductor structure, e.g., the channel region 130) may be a planar structure or a non-planar structure. A non-planar structure is a three-dimensional structure, such as fin, nanowire, or nanoribbon. A non-planar structure may have a longitudinal axis and a transvers cross-section perpendicular to the longitudinal axis. In some embodiments, a dimension of the non-planar structure along the longitudinal axis may be greater than dimensions along other directions, e.g., directions along axes perpendicular to the longitudinal axis.

The channel region 130 includes a channel material. The channel material may be composed of semiconductor material systems including, for example, n-type or p-type materials systems. In some embodiments, the channel material may include a high mobility oxide semiconductor material, such as tin oxide, antimony oxide, indium oxide, indium tin oxide, titanium oxide, zinc oxide, indium zinc oxide, gallium oxide, titanium oxynitride, ruthenium oxide, or tungsten oxide. In some embodiments, the channel material may include a compound semiconductor with a first sub-lattice of at least one element from Group III of the periodic table (e.g., Al, Ga, In), and a second sub-lattice of at least one element of group V of the periodic table (e.g., P, As, Sb). In some embodiments, the channel material may include a compound semiconductor with a first sub-lattice of at least one element from Group II of the periodic table (e.g., Zn, Cd, Hg), and a second sub-lattice of at least one element of Group IV of the periodic table (e.g., C, Si, Ge, Sn, Pb). In some embodiments, the channel material is an epitaxial semiconductor material deposited using an epitaxial deposition process. The epitaxial semiconductor material may have a polycrystalline structure with a grain size between about 2 nm and 100 nm, including all values and ranges therein.

For some example n-type transistor embodiments (i.e., for the embodiments where the transistor 117 is an NMOS (N-type metal-oxide-semiconductor) transistor or an n-type TFET), the channel material may advantageously include a III-V material having a high electron mobility, such as, but not limited to InGaAs, InP, InSb, and InAs. For some such embodiments, the channel material may be a ternary III-V alloy, such as InGaAs, GaAsSb, InAsP, or InPSb. For some InxGa1-xAs fin embodiments, In content (x) may be between 0.6 and 0.9, and may advantageously be at least 0.7 (e.g., In0.7Ga0.3As). In some embodiments with highest mobility, the channel material may be an intrinsic III-V material, i.e., a III-V semiconductor material not intentionally doped with any electrically active impurity. In alternate embodiments, a nominal impurity dopant level may be present within the channel material, for example to further fine-tune a threshold voltage Vt, or to provide HALO pocket implants, etc. Even for impurity-doped embodiments however, impurity dopant level within the channel material 304 may be relatively low, for example below 1015 dopant atoms per cubic centimeter (cm-3), and advantageously below 10¹³ cm⁻³. These materials may be amorphous or polycrystalline, e.g., having a crystal grain size between 0.5 nanometers and 100 nanometers.

For some example p-type transistor embodiments (i.e., for the embodiments where the transistor 117 is a PMOS (P-type metal-oxide-semiconductor) transistor or a p-type TFET), the channel material may advantageously be a Group IV material having a high hole mobility, such as, but not limited to Ge or a Ge-rich SiGe alloy. For some example embodiments, the channel material may have a Ge content between 0.6 and 0.9, and advantageously may be at least 0.7. In some embodiments with highest mobility, the channel material may be intrinsic III-V (or IV for P-type devices) material and not intentionally doped with any electrically active impurity. In alternate embodiments, one or more a nominal impurity dopant level may be present within the channel material, for example to further set a threshold voltage (Vt), or to provide HALO pocket implants, etc. Even for impurity-doped embodiments however, impurity dopant level within the channel portion is relatively low, for example below 10¹⁵ cm⁻³, and advantageously below 10¹³ cm⁻³. These materials may be amorphous or polycrystalline, e.g., having a crystal grain size between 0.5 nanometers and 100 nanometers.

In some embodiments, the channel material may include a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, aluminum zinc oxide, or tungsten oxide. In general, for a thin-film transistor (TFT), the channel material may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, molybdenum disulfide, N- or P-type amorphous or polycrystalline silicon, monocrystalline silicon, germanium, indium arsenide, indium gallium arsenide, indium selenide, indium antimonide, zinc antimonide, antimony selenide, silicon germanium, gallium nitride, aluminum gallium nitride, indium phosphite, black phosphorus, zinc sulfide, indium sulfide, gallium sulfide, each of which may possibly be doped with one or more of gallium, indium, aluminum, fluorine, boron, phosphorus, arsenic, nitrogen, tantalum, tungsten, and magnesium, etc. In some embodiments, a thin-film channel material may be deposited at relatively low temperatures, which allows depositing the channel material within the thermal budgets imposed on back-end fabrication to avoid damaging other components, e.g., front end components such as logic devices.

As noted above, the channel material may include IGZO. IGZO-based devices have several desirable electrical and manufacturing properties. IGZO has high electron mobility compared to other semiconductors, e.g., in the range of 20-50 times than amorphous silicon. Furthermore, amorphous IGZO (a-IGZO) transistors are typically characterized by high band gaps, low-temperature process compatibility, and low fabrication cost relative to other semiconductors.

IGZO can be deposited as a uniform amorphous phase while retaining higher carrier mobility than oxide semiconductors such as zinc oxide. Different formulations of IGZO include different ratios of indium oxide, gallium oxide, and zinc oxide. One particular form of IGZO has the chemical formula InGaO₃(ZnO)₅. Another example form of IGZO has an indium:gallium:zinc ratio of 1:2:1. In various other examples, IGZO may have a gallium to indium ratio of 1:1, a gallium to indium ratio greater than 1 (e.g., 2:1, 3:1, 4:1, 5:1, 6:1, 7:1, 8:1, 9:1, or 10:1), and/or a gallium to indium ratio less than 1 (e.g., 1:2, 1:3, 1:4, 1:5, 1:6, 1:7, 1:8, 1:9, or 1:10). IGZO can also contain tertiary dopants such as aluminum or nitrogen.

The source region 140A and the drain region 140B are connected to the channel region 130. The source region 140A and the drain region 140B each includes a semiconductor material with dopants. In some embodiments, the source region 140A and the drain region 140B have the same semiconductor material, which may be the same as the channel material of the channel region 130. A semiconductor material of the source region 140A or the drain region 140B may be a Group IV material, a compound of Group IV materials, a Group III/V material, a compound of Group III/V materials, a Group II/VI material, a compound of Group II/VI materials, or other semiconductor materials. Example Group II materials include zinc (Zn), cadmium (Cd), and so on. Example Group III materials include aluminum (Al), boron (B), indium (In), gallium (Ga), and so on. Example Group IV materials include silicon (Si), germanium (Ge), carbon (C), etc. Example Group V materials include nitrogen (N), phosphorus (P), arsenic (As), antimony (Sb), and so on. Example Group VI materials include sulfur (S), selenium (Se), tellurium (Te), oxygen (O), and so on. A compound of Group IV materials can be a binary compound, such as SiC, SiGe, and so on. A compound of Group III/V materials can be a binary, tertiary, or quaternary compound, such as GaN, InN, and so on. A compound of Group II/VI materials can be a binary, tertiary, or quaternary compounds, such as CdSe, CdS, CdTe, ZnO, ZnSe, ZnS, ZnTe, CdZnTe, CZT, HgCdTe, HgZnTe, and so on.

In some embodiments, the dopants in the source region 140A and the drain region 140B are the same type. In other embodiments, the dopants of the source region 140A and the drain region 140B may be different (e.g., opposite) types. In an example, the source region 140A has n-type dopants and the drain region 140B has p-type dopants. In another example, the source region 140A has p-type dopants and the drain region 140B has n-type dopants. Example n-type dopants include Te, S, As, tin (Sn), Si, Ga, Se, S, In, Al, Cd, chlorine (CI), iodine (I), fluorine (F), and so on. Example p-type dopants include beryllium (Be), Zn, magnesium (Mg), Sn, P, Te, lithium (Li), sodium (Na), Ga, Cd, and so on.

In some embodiments, the source region 140A and the drain region 140B may be highly doped, e.g., with dopant concentrations of about 1·10²¹ cm⁻³, in order to advantageously form Ohmic contacts with the respective S/D contacts (also sometimes interchangeably referred to as “S/D electrodes”), although these regions may also have lower dopant concentrations and may form Schottky contacts in some implementations. Irrespective of the exact doping levels, the source region 140A and the drain region 140B may be the regions having dopant concentration higher than in other regions, e.g., higher than a dopant concentration in the channel region 130, and, therefore, may be referred to as “highly doped” (HD) regions.

The channel region 130 may include one or more semiconductor materials with doping concentrations significantly smaller than those of the source region 140A and the drain region 140B. For example, in some embodiments, the channel material of the channel region 130 may be an intrinsic (e.g., undoped) semiconductor material or alloy, not intentionally doped with any electrically active impurity. In alternate embodiments, nominal impurity dopant levels may be present within the channel material, for example to set a threshold voltage Vt, or to provide HALO pocket implants, etc. In such impurity-doped embodiments however, impurity dopant level within the channel material is still significantly lower than the dopant level in the source region 140A and the drain region 140B, for example below 10¹⁵ cm⁻³ or below 10¹³ cm⁻³. Depending on the context, the term “S/D terminal” may refer to a S/D region or a S/D contact or electrode of a transistor.

The transistor 117 also includes a source contact 145A over the source region 140A and a drain contact 145B over the drain region 140B. The source contact 145A and the drain contact 145B are electrically conductive and may be coupled to source and drain terminals for receiving electrical signals. The source contact 145A or the drain contact 145B includes one or more electrically conductive materials, such as metals. Examples of metals in the source contact 145A and the drain contact 145B may include, but are not limited to, Ru, Cu, Co, palladium (Pd), platinum (Pt), nickel (Ni), and so on.

The transistor 117 also includes a gate that is over or wraps around at least a portion of the channel region 130. The gate includes a gate electrode 135 and a gate insulator 137. The gate electrode 135 can be coupled to a gate terminal that controls gate voltages applied on the transistor 117. The gate electrode 135 may include one or more gate electrode materials, where the choice of the gate electrode materials may depend on whether the transistor 117 is a p-type transistor or an n-type transistor. For a p-type transistor, gate electrode materials that may be used in different portions of the gate electrode may include, but are not limited to, Ru, Pd, Pt, Co, Ni, and conductive metal oxides (e.g., ruthenium oxide). For an n-type transistor, gate electrode materials that may be used in different portions of the gate electrode, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide). In some embodiments, the gate electrode 135 may include a stack of a plurality of gate electrode materials, where zero or more materials of the stack are workfunction (WF) materials and at least one material of the stack is a fill metal layer. Further materials/layers may be included next to the gate electrode for other purposes, such as to act as a diffusion barrier layer or/and an adhesion layer.

The gate insulator 137 separates at least a portion of the channel region 130 from the gate electrode 135 so that the channel region 130 is insulated from the gate electrode 135. In some embodiments, the gate insulator 137 may wrap around at least a portion of the channel region 130. The gate insulator 137 may also wrap around at least a portion of the source region 140A or the drain region 140B. At least a portion of the gate insulator 137 may be wrapped around by the gate electrode. The gate insulator 137 includes an electrical insulator, such as a dielectric material, hysteretic material, and so on. Example dielectric material includes oxide (e.g., Si based oxides, metal oxides, etc), high-k dielectric, and so on. Example hysteretic material include ferroelectric materials, antiferroelectric materials, etc.

As shown in FIG. 1A, the transistor 117 is coupled to the metal layer, particularly to a metal line 160 and two metal lines 180 in the metal layer. The metal layer may facilitate controlling operation of the transistor 117 by providing electrical signals to the transistor 117, such as the source contact 145A, the drain contact 145B, or the gate electrode 135. In the embodiments of FIG. 1A, the transistor 117 and the metal layer are coupled through vias 150A-150C (collectively referred to as “vias 150” or “via 150”). A via 150 may be electrically conductive. A via 150 may include a metal, such as tungsten (W), molybdenum (Mo), ruthenium (Ru), or other metals. Different vias 150 may include different materials. The vias 150 can provide a conductive channel between the transistor 117 and the metal layer. The vias 150A-150C are separated from each other by one or more electrical insulators in the insulative structure 119. The insulative structure 119 may include one or more electrical insulators. An electrical insulator may be a dielectric material, hysteretic material, and so on. Example dielectric material includes oxide (e.g., Si based oxides, metal oxides, etc), low-k dielectric, high-k dielectric, and so on. Example hysteretic material include ferroelectric materials, antiferroelectric materials, etc.

A via 150 may have two ends: one end connected to an electrode of the transistor 117 and the other end connected to a metal line 160 or 180. For purpose of illustration, the via 150A is connected to the source contact 145A and a metal line 180, the via 150B is connected to the gate electrode 135 and a metal line 180, and the via 150C is connected to the drain contact 145B and another metal line 180. In other embodiments, the transistor 117 may be coupled to the metal layer through a different number of vias 150. In other embodiments, the electrical connection between the metal layer and the transistor 117 may be different. Even though not shown in FIG. 1, the metal layer may be coupled with other devices than the transistor 117, such as diodes, power sources, resistors, capacitors, inductors, sensors, transceivers, receivers, antennas.

Each of the metal lines 160 and 180 is an electrically conductive structure. The metal lines 160 and 180 may also be referred to as electrically conductive interconnects or interconnects. The metal layer may also be referred to as an electrically conductive interconnect set or an interconnect set. In some embodiments, a metal line 160 or 180 includes a metal, such as W, Ru, Mo, Cu, or other metals. The metal lines 160 and 180 are shown as rectangles in FIGS. 1A and 1B. The metal lines 160 and 180 may have different shapes in other embodiments. Some or all of the metal lines 160 and 180 may be at different electrical potentials during operation of the IC device 100. The metal lines 160 and 180 are insulated from each other by one or more electrical insulators in the electrical insulator 125 and the insulative structures 170. Some portions of the electrical insulator 125 are between the metal lines 160 and 180. A portion of each insulative structure 170 is over a metal line 160 in a direction along the Z axis.

The electrical insulator 125 or insulative structure 170 may include one or more insulative materials. An insulative material may be a dielectric material, hysteretic material, and so on. Example dielectric material includes oxide (e.g., Si based oxides, metal oxides, etc.), nitride (e.g., Si based nitride, etc.), low-k dielectric, high-k dielectric, and so on. Example hysteretic material include ferroelectric materials, antiferroelectric materials, and so on. In some embodiments, the insulative structures 125 and 170 may include the same electrical insulator(s). In other embodiments, the insulative structures 125 and 170 may include different electrical insulators.

The metal lines 160 and 180 are arranged in parallel along the Z axis or Y axis. A metal line 160 has an axis 165 along the Z axis. The axis 165 may be through a center of a cross-section of the metal line 160 in the X-Z plane. A metal line 180 has an axis 185 along the Z axis. The axis 185 may be through a center of a cross-section of the metal line 180 in the X-Z plane. In some embodiments, a metal line 160 or 180 may have a longitudinal axis along the Y axis and have a transvers cross-section in the X-Z plane, which is shown in FIG. 1A. In some embodiments, a dimension of a metal line 160 or 180 along the Y axis may be greater than a dimension of the metal line 160 or 180 along the X axis or Z axis.

The metal layer has a pitch 127. The pitch 127 may equal to the center-to-center distance between two adjacent metal lines 160 and 180 along the X axis, such as the distance along the X axis between the axis 165 of a metal line 160 and the axis 185 of the metal line 180 that is adjacent to the metal line 160. In some embodiments, the pitch 127 is no greater than 24 nm. In an embodiment, the pitch 127 is in a range between about 10 nm and 24 nm. As an example, the pitch 127 may be about 18 nm.

As shown in FIG. 1A, the metal lines 160 are shorter than the metal lines 180 in a direction along the Z axis. In some embodiments, the metal lines 160 and 180 may be formed through serial DSA processes. For instance, the metal lines 160 are formed through a first DSA process, and the metal lines 180 are formed through a second DSA process that occurs after the first DSA process. The taller metal lines in the metal layer can facilitate creation of taller memory devices (e.g., SRAM) that would give lower resistance.

The serial DSA processes may also facilitate the formation of a metal cut (not shown in FIG. 1A). The metal cut may be at least partially surrounded by a metal line 160. For instance, the metal cut may be between two portions of the metal line 160. The metal cut may be formed by forming an opening within the metal line 160 and further by filling the opening with an electrical insulator. The metal cut may be between two portions of a metal line 160. The metal cut separates the two portions so that the two portions are insulated from each other. The metal cut may cross multiple metal lines 160. The BEOL section 120 may include one or more other metal cuts associated with other metal lines 160 or 180.

In some embodiments (e.g., embodiments where the metal lines 160 and 180 are formed through serial DSA processes), the metal cut may be formed after the first DSA process but before the second DSA process. As shown in FIG. 1B, a pitch 169 between two adjacent metal lines 160 after the first DSA process can be wider than the pitch 127 after the second DSA process. In some embodiments, the pitch 169 may be about two times of the pitch 127. In the example where the pitch 127 is 18 nm, the pitch 169 may be about 36 nm. The wider pitch can provide more space to form the metal cut. Also, the second DSA process can heal over the metal cut to create self-aligned insulative structures 173 over the metal lines 160. Another benefit of the serial DSA processes is that the metal lines 160 and 180 can have smoother surfaces compared with metal lines formed through currently available technologies given the better alignment that can be achieved through the DSA processes. The line edge roughness of a metal line 160 or 180 can be between about 1.1 nm and 1.5 nm, versus the line edge roughness of a metal line formed through currently available technologies may be between about 1.7 nm and 2 nm. Line edge roughness indicates a deviation of an edges in a pattern structure (e.g., a metal line 160 or 180) from the mean straight line. More details regarding line edge roughness of metal lines formed through serial DSA processes are provided below in conjunction with FIG. 7D.

In the embodiments of FIG. 1A, each insulative structure 173 has an axis 177 along the Z axis. The axis 177 may be through a center of a cross-section of the insulative structure 173 in the X-Z plane. The axis 177 is aligned with the axis 165 of the metal line 160 that is over the insulative structure 173. As shown in FIG. 1A, the axes 165 and 177 are in one straight line along the Z axis. In some embodiments, the length of the insulative structure 173 along the X axis may be the same or similar to the length of the metal line 160 along the X axis. Each insulative structure 173 is at least partially wrapped around by an insulative structure 175. In some embodiments, the insulative structure 175 includes the same material as the insulative structure 173. In other embodiments, the insulative structure 175 may include a different material from the insulative structure 173. Examples of a material in the insulative structure 173 or 175 may include silicon oxide (SiO), silicon nitride (SiN), silicon carbide (SiC), silicon oxynitride (SiOₓN_{y}, where x and y are integers), and so on.

A pair of an insulative structure 173 and the corresponding insulative structure 175 constitutes an insulative structure 170. The axis 177 of the insulative structure 173 in the pair may also be the axis of the insulative structure 170 along the Z axis. The axis 177 may be through a center of a cross-section of the insulative structure 170 in the X-Z plane. The dimension of the insulative structure 175 along the X axis can be controlled so that the dimension of the insulative structure 170 along the X axis can be controlled.

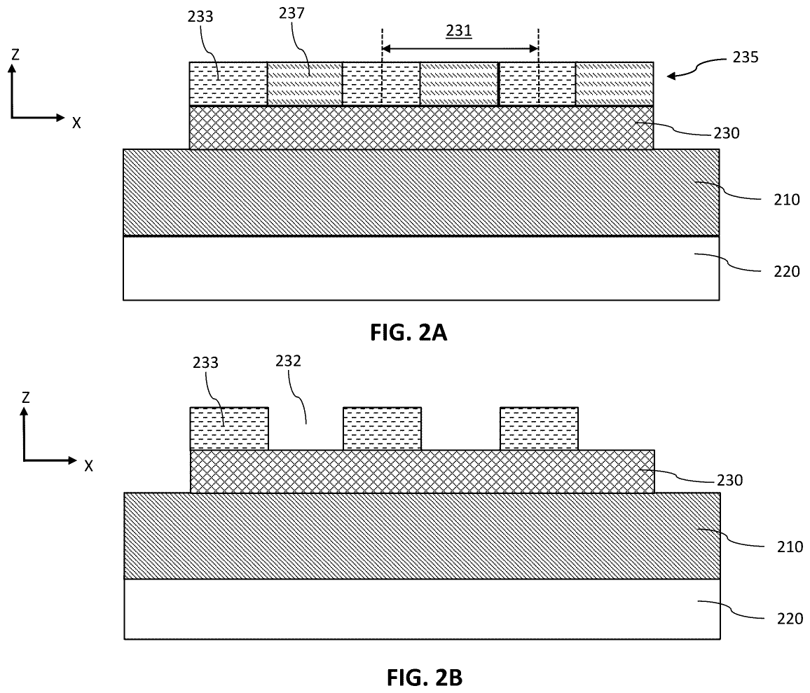

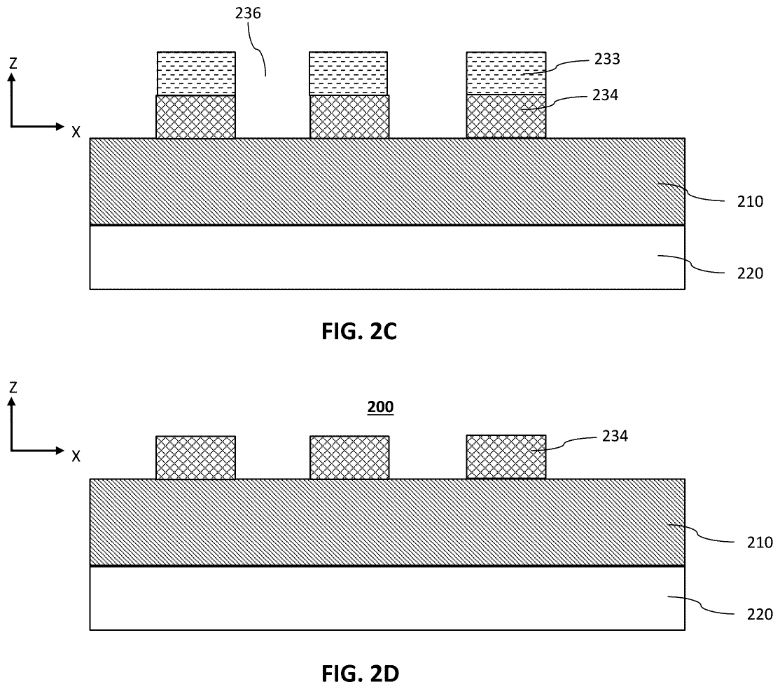

A metal line 180 can be formed between two adjacent insulative structures 170, as shown in FIGS. 1A and 1B. The length of the metal line 180 along the X axis may be controlled by controlling the dimension of the insulative structure 175 along the X axis. In some embodiments, the length of a metal line 180 may be the same or similar as the length of a metal line 160 along the X axis. More details regarding formation of the metal layer (e.g., formation of the metal lines 160, insulative structures 170, or metal lines 180) are provided below in conjunction with FIGS. 2A-2D, 3A-3D, 4A-4D, 5A-5D, 6A-6D, 7A-7D, and 8A-8D. Even though not shown in FIG. 1A, the BEOL section 120 may include one or more other metal layers that can be stacked over the metal layer along the Z axis. The metal layer may be the metal layer that is arranged closer to the FEOL section 110 than one or more other metal layers. In some embodiments, the metal layer may be referred to as M0, i.e., the metal layer that is arranged closest to the FEOL section 110. In other embodiments, the metal layer may be M1, M2, M3, and so on.

FIGS. 2A-2D illustrate an example DSA process for forming hard masks over a conductive layer 210, according to some embodiments of the disclosure. In FIG. 2A, the conductive layer 210 is over a layer 220. An embodiment of the layer 220 may include the insulative structure 119 in FIG. 1A. The conductive layer 210 may be formed by depositing one or more electrically conductive materials onto the top surface of the layer 220. The conductive layer 210 may include one or more metals, such as W, Ru, Cu, Mo, and so on, or one or more other types of electrically conductive materials. A dielectric layer 230 is formed over the conductive layer 210, e.g., by providing (such as depositing) a dielectric material onto the top surface of the conductive layer 210. The dielectric material may be electrically insulative. The dielectric material may be SiN, SiO, SiC, SiOₓN_{y}, other types of dielectric materials, or some combination thereof.

Also, a layer 235 is formed on the top surface of the dielectric layer 230. The layer 235 has an alternating pattern in which structures 233 (individually referred to as “structure 233”) alternatives with structures 237 (individually referred to as “structure 237”). The structures 233 and 237 may include two different polymers. The layer 235 can be formed through DSA of a diblock copolymer. The diblock copolymer may include two types of monomers: A and B. The diblock copolymer may have a phase (e.g., a lamellar phase) that has a periodic distribution of A and B. In the embodiment of FIG. 2A, the structures 233 include one of the monomers, and the structurers 237 include the other monomer. In an example, the structures 233 include polystyrene (PS), and the structures 237 include poly(methyl methacrylate) (PMMA). In another example, the structures 233 include PMMA, and the structures 237 include PS.

In some embodiments, the DSA of the diblock copolymer may be facilitated by a guiding pattern that can guide microphase separation of the diblock copolymer. The diblock copolymer may self-assembly and form lamellar structures based on the guiding pattern. The guiding pattern may be a topographical guiding pattern, a chemical guiding pattern, or a combination of both. An example topographical guiding pattern may include walls and openings between the walls, and the self-assembly of the diblock copolymer is drive by the physical boundaries. An example chemical guiding pattern may include sections that have stronger chemical affinity to polymer A than polymer B or sections that have stronger chemical affinity to polymer B than polymer A, and the self-assembly of the diblock copolymer is drive by the differentiated chemical affinities.

The alternating pattern of the structures 233 and 237 is also referred to as a DSA pattern. The DSA pattern has a pitch 231, which may be the center-to-center distance between two adjacent structures 233 (or between two adjacent structures 237). The pitch 231 may be between about 20 nm and 48 nm. In an example, the pitch 231 may be 36 nm.

In FIG. 2B, the structures 237 are removed from the layer 235, e.g., through selective etch. The structures 237 may be etched at a faster rate than the structures 233 in the selective etch. The removal of the structures 237 forms openings 232 (individually referred to as opening 232) in the layer 235.

In FIG. 2C, portions of the dielectric layer 230 that are under the openings 232 are removed, e.g., by etching. Openings 236 (individually referred to as opening 236) that are through the layer 235 and the dielectric layer 230 are formed. Also, structures 234 are formed. The structures 234 are separated from each other. Each structure 234 is over a structure 233. Edges of the structure 234 along the Z axis may be aligned with edges of the structure 233 along the Z axis.

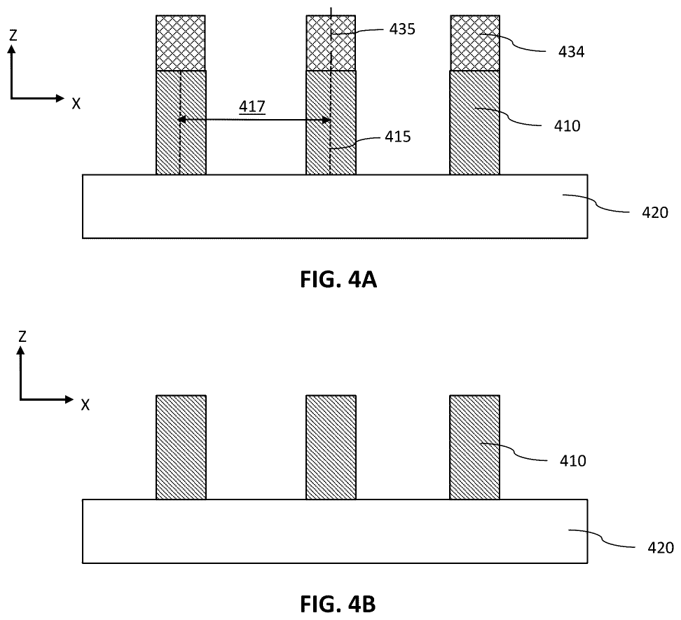

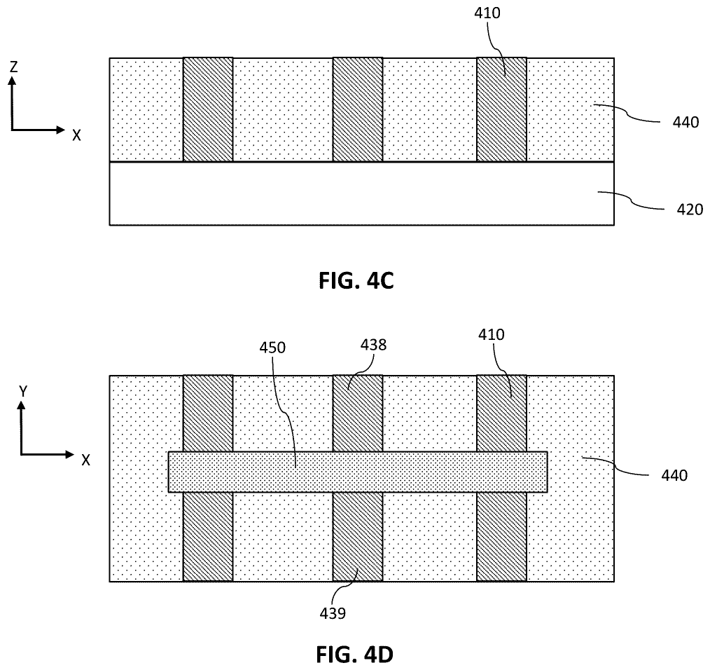

In FIG. 2D, an assembly 200 is produced. The assembly 200 includes the conductive layer 210, the layer 220, and structures 234. The structures 233 are removed, e.g., through selective etch. The structures 233 may be etched at a faster rate than the structures 234. The structures 234 are separated from each other by openings 236 (individually referred to as opening 236). The structures 234 may be referred to as hard masks. The assembly 200 (particularly the structures 234) can be used to form metal lines, e.g., through the process described below in conjunction with FIGS. 4A-4D.

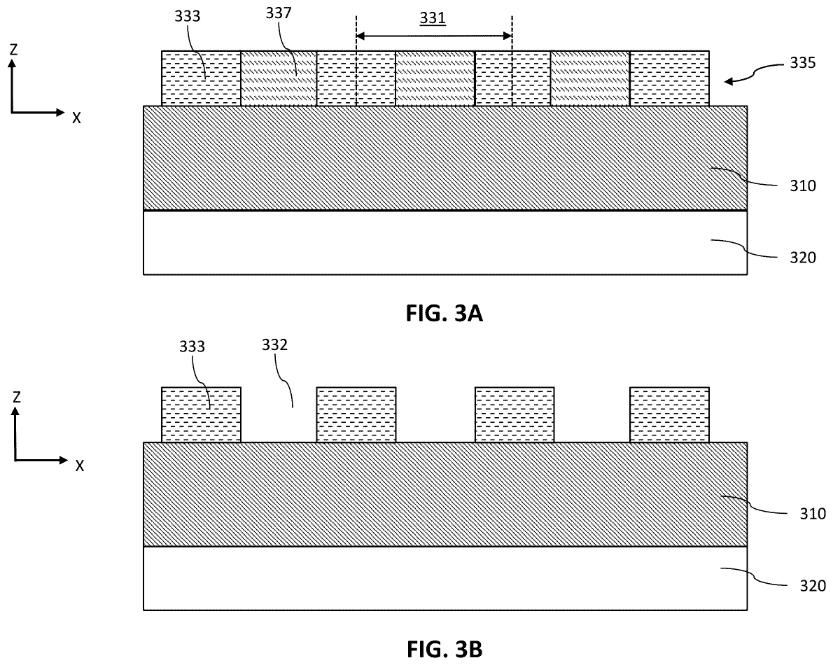

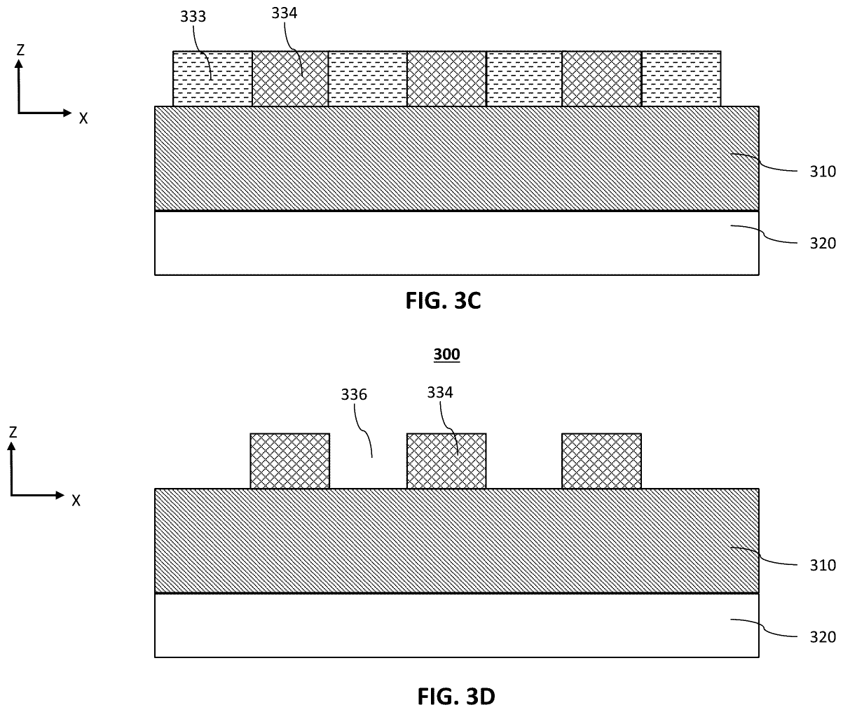

FIGS. 3A-3D illustrate another example DSA process for forming hard masks over a conductive layer 310, according to some embodiments of the disclosure. In FIG. 3A, the conductive layer 310 is over a layer 320. An embodiment of the layer 320 may include the insulative structure 119 in FIG. 1A. The conductive layer 310 may be formed by depositing a metal onto the top surface of the layer 320. The conductive layer 310 may include one or more metals, such as W, Ru, Cu, Mo, and so on. Also, a layer 335 is formed on the top surface of the conductive layer 310. The layer 335 has an alternating pattern in which structures 333 (individually referred to as “structure 333”) alternatives with structures 337 (individually referred to as “structure 337”). The structures 333 and 337 may include two different polymers. The layer 335 can be formed through DSA of a diblock copolymer. The diblock copolymer may include two types of monomers: A and B. The diblock copolymer may have a phase (e.g., a lamellar phase) that has a periodic distribution of A and B. In the embodiment of FIG. 3A, the structures 333 include one of the monomers, and the structurers 337 include the other monomer. In an example, the structures 333 include polystyrene (PS), and the structures 337 include poly(methyl methacrylate) (PMMA). In another example, the structures 333 include PMMA, and the structures 337 include PS.

In some embodiments, the DSA of the diblock copolymer may be facilitated by a guiding pattern that can guide microphase separation of the diblock copolymer. The diblock copolymer may self-assembly and form lamellar structures based on the guiding pattern. The guiding pattern may be a topographical guiding pattern, a chemical guiding pattern, or a combination of both. An example topographical guiding pattern may include walls and openings between the walls, and the self-assembly of the diblock copolymer is drive by the physical boundaries. An example chemical guiding pattern may include sections that have stronger chemical affinity to polymer A than polymer B or sections that have stronger chemical affinity to polymer B than polymer A, and the self-assembly of the diblock copolymer is drive by the differentiated chemical affinities.

The alternating pattern of the structures 333 and 337 is also referred to as a DSA pattern. The DSA pattern has a pitch 331, which may be the center-to-center distance between two adjacent structures 333 (or between two adjacent structures 337). The pitch 231 may be between about 20 nm and 48 nm. In an example, the pitch 231 may be 36 nm.

In FIG. 3B, the structures 337 are removed from the layer 335, e.g., through selective etch. The structures 337 may be etched at a faster rate than the structures 333 in the selective etch. The removal of the structures 337 forms openings 332 (individually referred to as opening 332) in the layer 335.

In FIG. 3C, structures 334 (individually referred to as structure 334) are formed in the openings 332, e.g., by providing (such as depositing) a dielectric material into the openings 332. The dielectric material may be SiN, SiO, SiC, SiOₓN_{y}, other types of dielectric materials, or some combination thereof. The dielectric material may be electrically insulative. The positions or dimensions of the structures 334 may be the same or similar as the positions or dimensions of the structures 337. The formation of the structures 334 is facilitated by the DSA pattern in the layer 335.

In FIG. 3D, an assembly 300 is produced. The assembly 300 includes the conductive layer 310, the layer 320, and structures 334. The structures 333 are removed, e.g., through selective etch. The structures 333 may be etched at a faster rate than the structures 334. The structures 334 are separated from each other by openings 336 (individually referred to as opening 336). The structures 334 may be referred to as hard masks. The assembly 300 (particularly the structures 334) can be used to form metal lines, e.g., through the process described below in conjunction with FIGS. 4A-4D.

FIGS. 4A-4D illustrates a process of forming metal lines 410, according to some embodiments of the disclosure. The process may start with an assembly that includes hard masks and a metal layer. Examples of the assembly include the assembly 200 in FIG. 2D or the assembly 300 in FIG. 3D. In FIG. 4A, the metal lines 410 (individually referred to as metal line 410) are formed over a layer 420. An embodiment of a metal line 410 is the metal line 160 in FIG. 1A. An embodiment of the layer 420 may be the layer 220 or the layer 320. The metal lines 410 are between the layer 420 and structures 434 (individually referred to as structure 434). Each metal line 410 is under a structure 434. An embodiment of the structure 434 may be the structure 234 in FIG. 2D or the structure 334 in FIG. 3D. In some embodiments, the metal lines 410 are formed by removing portions of a metal layer (e.g., the conductive layer 210 in FIG. 2D or 310 in FIG. 3D) that are under the openings between the structures 434. The portions of the metal layer may be removed through etching. The structures 434 may be formed based on a DSA pattern in a DSA process, such as the DSA process illustrated in FIGS. 2A-2D or the DSA process illustrated in FIGS. 3A-3D. Accordingly, the metal lines 410 are formed based on the DSA pattern. Edges of the metal lines 410 can be smooth given the alignment achieved through the DSA pattern. In some embodiments, a line edge roughness of a metal line 410 may be between about 1.1 nm and 1.5 nm.

As shown in FIG. 4A, a metal line 410 has an axis 415 along the Z axis, and a structure 434 has an axis 435 along the Z axis. The longitudinal axes 415 and 435 are aligned. A pitch 417 of the metal lines 410 is a center-to-center distance between two adjacent metal lines 410 along the X axis. The pitch 417 may be between about 30 nm and 48 nm. In some embodiments, the pitch 417 may be the same or similar as the pitch of the DSA pattern, such as the pitch 231 in FIG. 2A or the pitch 331 in FIG. 3A.

In FIG. 4B, the structures 434 are removed, e.g., through etching. The metal lines 410 may not be etched or may be slightly etched. The pitch 417 of the metal lines 410 may be the same as the pitch (e.g., the pitch 231 shown in FIG. 2A or the pitch 331 shown in FIG. 3A) of the DSA pattern from which the metal lines 410 are formed. The metal lines 410 may constitute a portion of a metal layer. The metal layer may be M0, M1, M2, etc. The pitch 417 is greater than the pitch of the metal layer. In some embodiments, the pitch 417 may be two times the pitch of the metal layer.

In FIG. 4C, an electrical insulator is provided to openings surrounding the metal lines 410, which forms an insulative structure 440 surrounding the metal lines 410. The electrical insulator may be a dielectric material, hysteretic material, and so on. Example dielectric material includes oxide (e.g., Si based oxides, metal oxides, etc.), nitride (e.g., Si based nitride, etc.), low-k dielectric, high-k dielectric, and so on. Example hysteretic material include ferroelectric materials, antiferroelectric materials, and so on. The electrical insulator may be referred to as interlayer dielectric (ILD). The metal lines 410 are separated and insulated from each other by the electrical insulator.

In FIG. 4D, a metal cut 450 is formed. For purpose of illustration, the metal cut 450 is formed in all the three metal lines 410. As shown in FIG. 4D, the metal cut 450 crosses all the three metal lines 410. In other embodiments, the metal cut 450 may be formed in one or two of the three metal lines 410. For instance, the metal cut 450 may be shorter along the X axis and may cross one or two the three metal lines 410. Even though the metal cut 450 has a rectangular cross-section in the X-Y plane, the cross-section of the metal cut may have a different shape than rectangular. Multiple metal cuts may be formed in one or more metal lines 410.

The length of the metal cut 450 along the X axis may vary and may at least partially depend on how many metal lines 410 are cut through. The width of the metal cut 450 along the Y axis may be less than or equal to the pitch 417. In some embodiments, the width of the metal cut 450 is no greater than 40 nm. The height of the metal cut 450 along the Z axis may be the same or similar as the height of a metal line 410 along the Z axis. The metal cut 450 may include one or more different insulative materials from the insulative structure 440.

In some embodiments, the metal cut 450 may be formed by forming an opening (e.g., a trench) within the metal lines 410 and the insulative structure 440. The opening may be at least partially surround by the metal lines 410 and the insulative structure 440. The opening may be filled with one or more dielectric materials to form the metal cut 450. The metal cut 450 may include one or more different dielectric materials from the insulative structure 440. As shown in FIG. 4D, a portion of the metal cut 450 is between a structure 438 and a structure 439, which are two separate portions of the metal line 410 in the middle. The structure 438 and structure 439 are insulated from each other by the portion of the metal cut 450. Similarly, a portion of the metal cut 450 is between portions of each of the other two metal lines 410.

In the embodiments of FIGS. 4A-4D, the metal cut 450 is formed after the structures 434 are removed. To form the metal cut 450 before removal of the structures 434, an opening is to be formed in a structure 434 and the metal line 410 below the structure 434. The opening can expand due to the presence of the dielectric material in the structure 434, which makes it difficult to precisely control the dimensions of the metal cut 450. In some embodiments, the opening may expand for about 3 nm. Thus, compared with forming the metal cut 450 before the removal of the structures 434, the process in FIGS. 4A-4D can more precisely control the dimension of the metal cut 450, e.g., the dimension along the X axis or the dimension along the Z axis. Also, it is beneficial to form the metal cut 450 before additional metal lines in the metal layer are formed. As the pitch 417 is wider than the final pitch of the metal layer, there can be more space to form the metal cut 450 before other metal lines in the metal layer are formed.

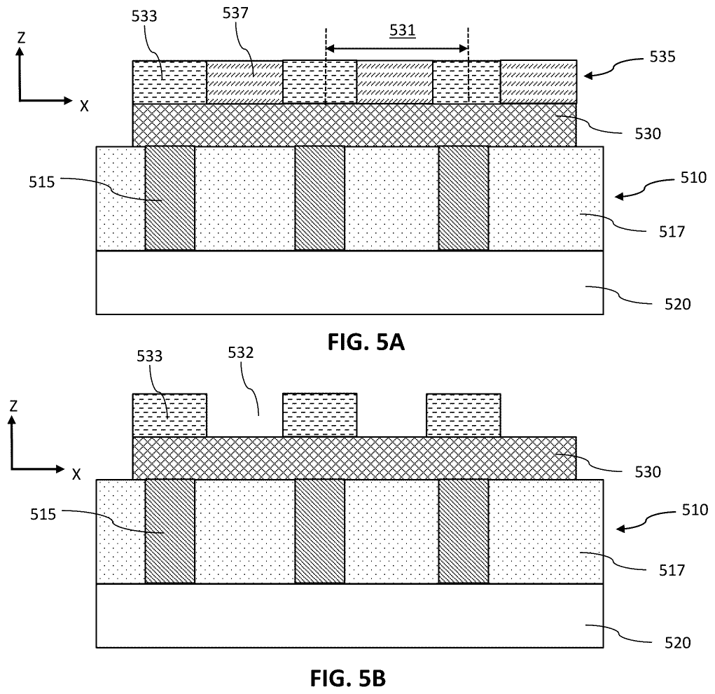

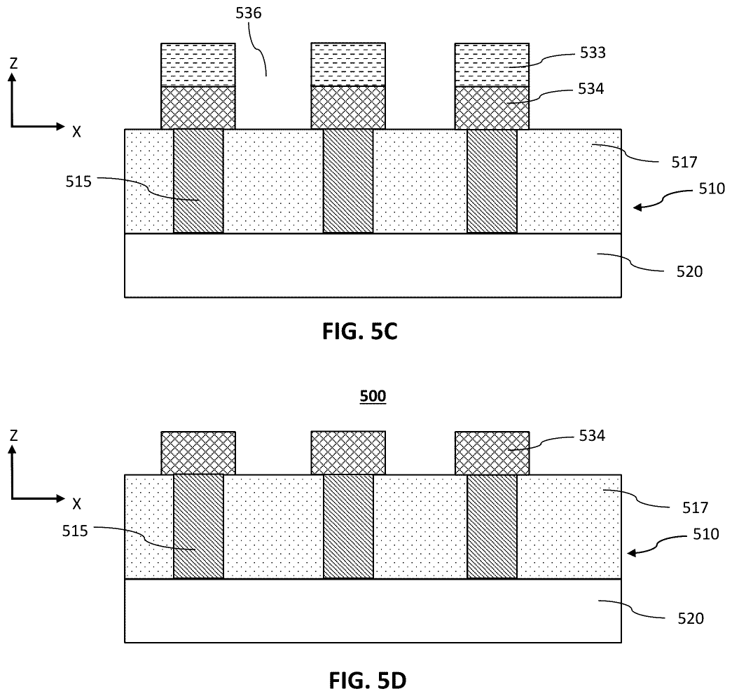

FIGS. 5A-5D illustrate an example DSA process for forming hard masks over a layer 510, according to some embodiments of the disclosure. As shown in FIG. 5A, the layer 510 includes metal lines 515 and an electrical insulator 517. Embodiments of the metal lines 515 may include the metal lines 160 in FIG. 1 or the metal lines 410 in FIG. 4D. The layer 510 is over a layer 520. The layer 520 includes an electrical insulator. In some embodiments, the layer 520 may include the same electrical insulator as the electrical insulator 517. In other embodiments, the layer 520 may include an electrical insulator that is different from the electrical insulator 517. An embodiment of the layer 520 may include the insulative structure 119 in FIG. 1A. A dielectric layer 530 is formed over the layer 510, e.g., by providing (such as depositing) a dielectric material onto the top surface of the layer 510. The dielectric material may be SiN, SiO, SiC, SiOₓN_{y}, other types of dielectric materials, or some combination thereof.

Also, a layer 535 is formed on the top surface of the dielectric layer 530. The layer 535 has an alternating pattern in which structures 533 (individually referred to as “structure 533”) alternatives with structures 537 (individually referred to as “structure 537”). The structures 533 and 537 may include two different polymers. The layer 535 can be formed through DSA of a diblock copolymer. The diblock copolymer may include two types of monomers: A and B. The diblock copolymer may have a phase (e.g., a lamellar phase) that has a periodic distribution of A and B. In the embodiment of FIG. 5A, the structures 533 include one of the monomers, and the structurers 537 include the other monomer. In an example, the structures 533 include polystyrene (PS), and the structures 537 include poly(methyl methacrylate) (PMMA). In another example, the structures 533 include PMMA, and the structures 537 include PS.

In some embodiments, the DSA of the diblock copolymer may be facilitated by a guiding pattern that can guide microphase separation of the diblock copolymer. The diblock copolymer may self-assembly and form lamellar structures based on the guiding pattern. The guiding pattern may be a topographical guiding pattern, a chemical guiding pattern, or a combination of both. An example topographical guiding pattern may include walls and openings between the walls, and the self-assembly of the diblock copolymer is drive by the physical boundaries. An example chemical guiding pattern may include sections that have stronger chemical affinity to polymer A than polymer B or sections that have stronger chemical affinity to polymer B than polymer A, and the self-assembly of the diblock copolymer is drive by the differentiated chemical affinities.

The alternating pattern of the structures 533 and 537 is also referred to as a DSA pattern. The DSA pattern has a pitch 531, which may be the center-to-center distance between two adjacent structures 533 (or between two adjacent structures 537). The pitch 531 may be between about 50 nm and 48 nm. In an example, the pitch 531 may be 36 nm.

In FIG. 5B, the structures 537 are removed from the layer 535, e.g., through selective etch. The structures 537 may be etched at a faster rate than the structures 533 in the selective etch. The removal of the structures 537 forms openings 532 (individually referred to as opening 532) in the layer 535.

In FIG. 5C, portions of the dielectric layer 530 that are under the openings 532 are removed, e.g., by etching. Openings 536 (individually referred to as opening 536) that are through the layer 535 and the dielectric layer 530 are formed. Also, structures 534 are formed. The structures 534 are separated from each other. Each structure 534 is over a structure 533. Edges of the structure 534 along the Z axis may be aligned with edges of the structure 533 along the Z axis.

In FIG. 5D, an assembly 500 is produced. The assembly 500 includes the layer 510, the layer 520, and structures 534. The structures 533 are removed, e.g., through selective etch. The structures 533 may be etched at a faster rate than the structures 534. The structures 534 are separated from each other by openings 536 (individually referred to as opening 536). The structures 534 may be referred to as hard masks. The assembly 500 (particularly the structures 534) can be used to form metal lines, e.g., through the process described below in conjunction with FIGS. 7A-7D.

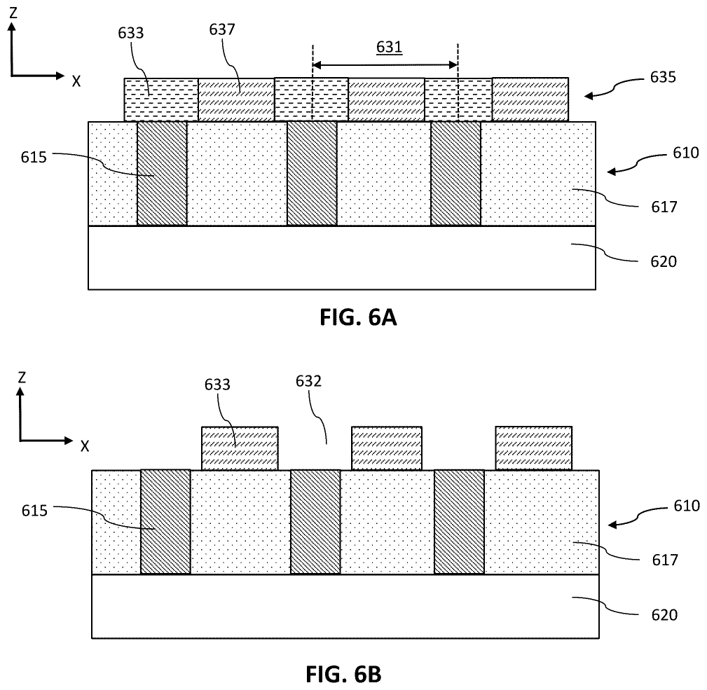

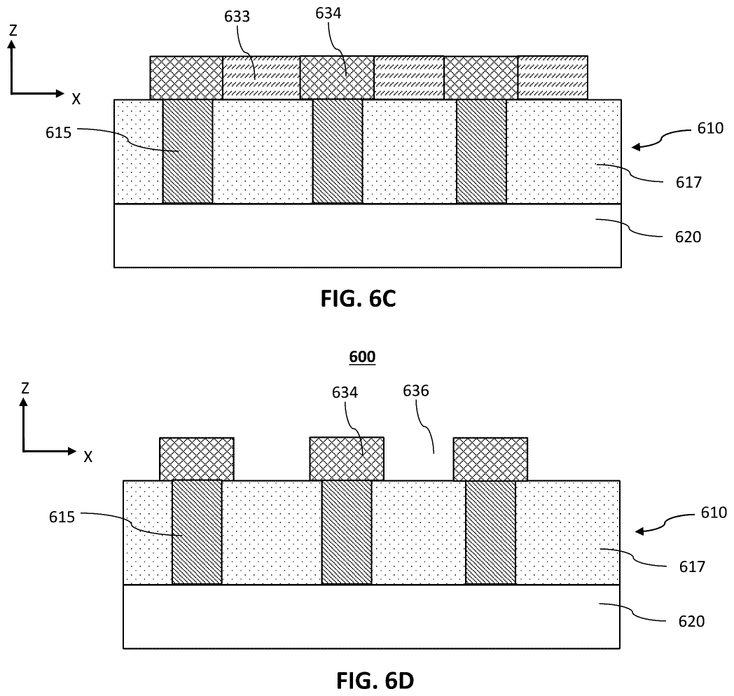

FIGS. 6A-6D illustrate another example DSA process for forming hard masks over a layer, according to some embodiments of the disclosure. As shown in FIG. 6A, the layer 610 includes metal lines 615 and an electrical insulator 617. Embodiments of the metal lines 615 may include the metal lines 160 in FIG. 1 or the metal lines 410 in FIG. 4D. The layer 610 is over a layer 620. The layer 620 includes an electrical insulator. In some embodiments, the layer 620 may include the same electrical insulator as the electrical insulator 617. In other embodiments, the layer 620 may include an electrical insulator that is different from the electrical insulator 617. An embodiment of the layer 620 may include the insulative structure 119 in FIG. 1A.

Also, a layer 635 is formed on the top surface of the layer 610. The layer 635 has an alternating pattern in which structures 633 (individually referred to as “structure 633”) alternatives with structures 637 (individually referred to as “structure 637”). The structures 633 and 637 may include two different polymers. The layer 635 can be formed through DSA of a diblock copolymer. The diblock copolymer may include two types of monomers: A and B. The diblock copolymer may have a phase (e.g., a lamellar phase) that has a periodic distribution of A and B. In the embodiment of FIG. 6A, the structures 633 include one of the monomers, and the structurers 637 include the other monomer. In an example, the structures 633 include polystyrene (PS), and the structures 637 include poly(methyl methacrylate) (PMMA). In another example, the structures 633 include PMMA, and the structures 637 include PS.

In some embodiments, the DSA of the diblock copolymer may be facilitated by a guiding pattern that can guide microphase separation of the diblock copolymer. The diblock copolymer may self-assembly and form lamellar structures based on the guiding pattern. The guiding pattern may be a topographical guiding pattern, a chemical guiding pattern, or a combination of both. An example topographical guiding pattern may include walls and openings between the walls, and the self-assembly of the diblock copolymer is drive by the physical boundaries. An example chemical guiding pattern may include sections that have stronger chemical affinity to polymer A than polymer B or sections that have stronger chemical affinity to polymer B than polymer A, and the self-assembly of the diblock copolymer is drive by the differentiated chemical affinities.

The alternating pattern of the structures 633 and 637 is also referred to as a DSA pattern. The DSA pattern has a pitch 631, which may be the center-to-center distance between two adjacent structures 633 (or between two adjacent structures 637). The pitch 631 may be between about 20 nm and 48 nm. In an example, the pitch 631 may be 36 nm. In some embodiments, the DSA process may be performed after the process shown in FIGS. 4A-4D. A metal cut, such as the metal cut 450, may be formed within some or all of the metal lines 615. A width of the metal cut along the Y axis is no greater than the pitch 631, so that the presence of the metal cut would not negatively impact the formation of the DSA pattern.

In FIG. 6B, the structures 637 are removed from the layer 635, e.g., through selective etch. The structures 637 may be etched at a faster rate than the structures 633 in the selective etch. The removal of the structures 637 forms openings 632 (individually referred to as opening 632) in the layer 635.

In FIG. 6C, structures 634 (individually referred to as structure 634) are formed in the openings 632, e.g., by providing (such as depositing) a dielectric material into the openings 632. The dielectric material may be SiN, SiO, SiC, SiOₓN_{y}, other types of dielectric materials, or some combination thereof. The positions or dimensions of the structures 634 may be the same or similar as the positions or dimensions of the structures 637. The formation of the structures 634 is facilitated by the DSA pattern in the layer 635.

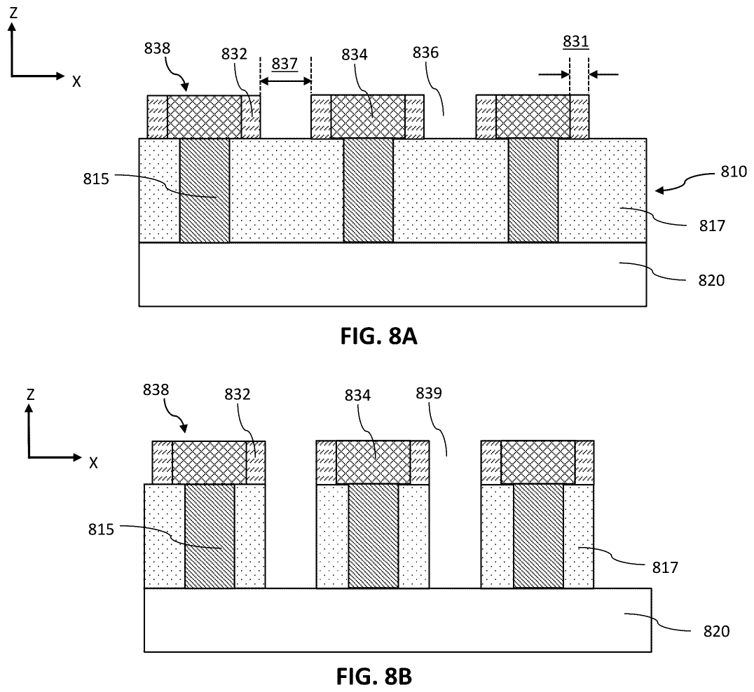

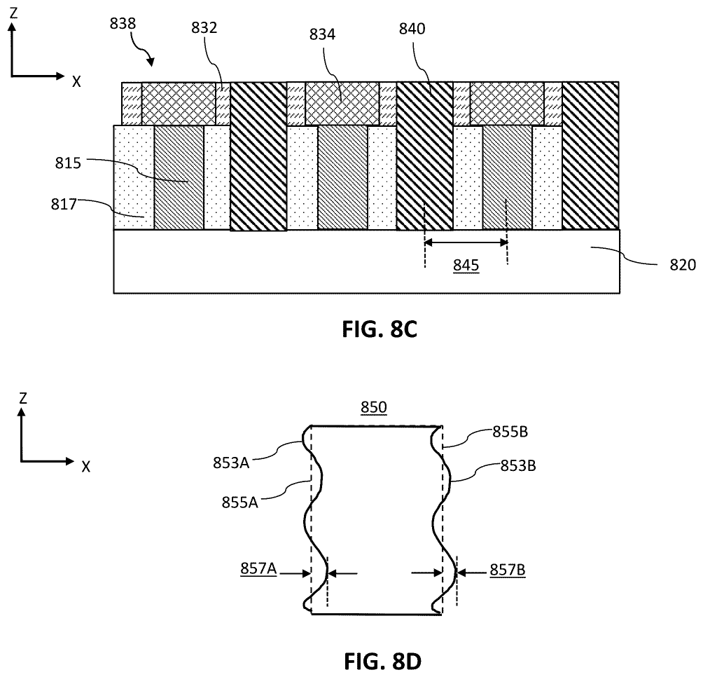

In FIG. 6D, an assembly 600 is produced. The assembly 600 includes the layer 610, the layer 620, and structures 634. The structures 633 are removed, e.g., through selective etch. The structures 633 may be etched at a faster rate than the structures 634. The structures 634 are separated from each other by openings 636 (individually referred to as opening 636). The structures 634 may be referred to as hard masks. The assembly 600 (particularly the structures 634) can be used to form metal lines, e.g., through the process described below in conjunction with FIGS. 8A-8D.

FIGS. 7A-7D illustrate yet another example DSA process for forming hard masks over a layer, according to some embodiments of the disclosure. As shown in FIG. 7A, the layer 710 includes metal lines 715 and an electrical insulator 717. Embodiments of the metal lines 715 may include the metal lines 160 in FIG. 1 or the metal lines 410 in FIG. 4D. The layer 710 is over a layer 720. The layer 720 includes an electrical insulator. In some embodiments, the layer 720 may include the same electrical insulator as the electrical insulator 717. In other embodiments, the layer 720 may include an electrical insulator that is different from the electrical insulator 717. An embodiment of the layer 720 may include the insulative structure 119 in FIG. 1A.

Also, a layer 735 is formed on the top surface of the layer 710. The layer 735 has an alternating pattern in which structures 733 (individually referred to as “structure 733”) alternatives with structures 737 (individually referred to as “structure 737”). The structures 733 and 737 may include two different polymers. The layer 735 can be formed through DSA of a diblock copolymer. The diblock copolymer may include two types of monomers: A and B. The diblock copolymer may have a phase (e.g., a lamellar phase) that has a periodic distribution of A and B. In the embodiment of FIG. 7A, the structures 733 include one of the monomers, and the structurers 737 include the other monomer. In an example, the structures 733 include polystyrene (PS), and the structures 737 include poly(methyl methacrylate) (PMMA). In another example, the structures 733 include PMMA, and the structures 737 include PS.

In some embodiments, the DSA of the diblock copolymer may be facilitated by a guiding pattern that can guide microphase separation of the diblock copolymer. The diblock copolymer may self-assembly and form lamellar structures based on the guiding pattern. The guiding pattern may be a topographical guiding pattern, a chemical guiding pattern, or a combination of both. An example topographical guiding pattern may include walls and openings between the walls, and the self-assembly of the diblock copolymer is drive by the physical boundaries. An example chemical guiding pattern may include sections that have stronger chemical affinity to polymer A than polymer B or sections that have stronger chemical affinity to polymer B than polymer A, and the self-assembly of the diblock copolymer is drive by the differentiated chemical affinities.

The alternating pattern of the structures 733 and 737 is also referred to as a DSA pattern. The DSA pattern has a pitch 731, which may be the center-to-center distance between two adjacent structures 733 (or between two adjacent structures 737). The pitch 731 may be between about 20 nm and 48 nm. In an example, the pitch 731 may be 36 nm. In some embodiments, the DSA process may be performed after the process shown in FIGS. 4A-4D. A metal cut, such as the metal cut 450, may be formed within some or all of the metal lines 715. A width of the metal cut along the Y axis is no greater than the pitch 731, so that the presence of the metal cut would not negatively impact the formation of the DSA pattern.

In FIG. 7B, the structures 737 are removed from the layer 735, e.g., through selective etch. The structures 737 may be etched at a faster rate than the structures 733 in the selective etch. The removal of the structures 737 forms openings 732 (individually referred to as opening 732) in the layer 735.

In FIG. 7C, each metal line 715 is recessed. A portion of each metal line 715 is removed, e.g., though etch. Each metal line 715 is converted to a metal line 719. The height of each metal line 715 along the Z axis is greater than the height of each metal line 719 along the Z axis. New openings 734 are formed.

In FIG. 7D, an assembly 700 is produced. The assembly 700 includes the layer 720, the electrical insulator 717, the metal lines 719, and dielectric structures 736. The structures 736 are separated from each other. In some embodiments, the dielectric structures 736 are formed by depositing a dielectric material into the opening 734. The dielectric material may be SiN, SiO, SiC, SiOₓN_{y}, other types of dielectric materials, or some combination thereof. The dielectric structures 736 may be referred to as hard masks. Even though the dielectric structures 736 extends beyond the top surface of the insulative structure 717 in FIG. 7D, the top surface of the dielectric structures 736 may be aligned with the top surface of the insulative structure 717 in other embodiments. In some embodiments, polish may be performed after the deposition of the dielectric material to remove excess dielectric material to form the dielectric structures 736. The assembly 700 (particularly the dielectric structures 736) can be used to form metal lines, e.g., through the process described below in conjunction with FIGS. 8A-8D. The structures 733 are removed, e.g., through selective etch. The structures 733 may be etched at a faster rate than the dielectric structures 736. In some embodiments, the structures 733 are removed before the deposition of the dielectric material. In other embodiments, the structures 733 are removed after the deposition of the dielectric material.

FIGS. 8A-8D illustrate a process of forming additional metal lines 840 for a metal layer, according to some embodiments of the disclosure. The process may start with an assembly that includes hard masks and a layer including pre-formed metal lines, e.g., metal lines 815 (individually referred to as metal line 815) shown in FIG. 8A. Examples of the assembly include the assembly 500 in FIG. 5D or the assembly 600 in FIG. 6D. The pre-formed metal lines may be the metal lines 515 or the metal lines 615.

In FIG. 8A, insulative structures 832 (individually referred to as insulative structure 832) are formed on side surfaces of structures 834 (individually referred to as structure 834). The structures 834 may be electrically insulative. Each structure 834 is over one of the metal lines 815. The metal lines 815 are insulated from each other by an electrical insulator 817, embodiments of which may be the electrical insulator 517 in FIGS. 5A-5D, the electrical insulator 617 in FIGS. 6A-6D, or the electrical insulator 717 in FIGS. 7A-7D. An insulative structure 832 wraps around the side surfaces of an individual structure 834. A pair of an insulative structure 832 and a structure 834 constitutes a structure 838. The axis of the structure 838 along the Z axis may be the same or similar as the axis of the structure 834 along the Z axis and may be aligned with the axis of the metal lines 815 under the structure 834 along the Z axis. Two adjacent structures 838 are separated by an opening 836 (plurally referred to as openings 836). The opening 836 is over the electrical insulator 817. The electrical insulator 817 and the metal lines 815 constitute a layer 810. The layer 810 is over another layer 820. The layer 820 may include an electrical insulator. Embodiments of the layer 820 include the FEOL section 110 and the layers 220, 320, 420, 520, and 620.

The insulative structures 832 may be formed by depositing an electrical insulator onto the top surface of the layer 810. In some embodiments, a thickness 831 of the insulative structures 832 in a direction along the X axis is predetermined. As the length of the structures 834 along the X axis is determined based on the DSA pattern. A length 837 of the openings 836 in the direction along the X axis can be determined based on the thickness 831 of the insulative structures 832. The length 837 of the openings 836 may further determine the length of the to-be-formed additional metal lines along the X axis.

In FIG. 8B, portions of the electrical insulator 817 that are under the openings 836 are removed, which forms openings 839. The openings 839 are through the layer 810 and extends to the top surface of the layer 820. The portions of the electrical insulator 817 may be removed through etch, such as dry etch. The openings 839 may have the same (or similar) length as the openings 836 in the direction along the X axis.

In FIG. 8C, the metal lines 840 (individually referred to as metal line 840) are formed over the layer 820. An embodiment of the metal lines 840 is the metal lines 180 in FIGS. 1A and 1B. Each metal line 840 may be formed by depositing one or more metals into an opening 839. The one or more metals may include W, Ru, Mo, Cu, other metals, or some combination thereof. The height of the metal lines 840 in a direction along the Z axis is greater than the height of the metal lines 815 in the direction. In some embodiments, the height of a metal line 840 may be the same or similar as the sum of the height of a metal line 815 and the height of a structure 838. The greater height of the metal lines 840 can facilitate usage of the metal layer in taller memory devices, such as taller SRAMs, with lower resistance.

The metal lines 815 and 840 constitute the metal layer, which may be M0, M1, M2, etc. of an IC device. The metal lines 815 and 840 may be formed in serial DSA processes, such as two separate DSA processes performed at different times. The alignment of the metal lines 815 and 840 may be facilitated by self-assembly of diblock copolymers in the DSA processes. The self-assembly of the diblock copolymers can determine the pitch of the metal layer, as discussed above in conjunction with FIGS. 2A-2D, 3A-3D, 4A-4D, 5A-5D, 6A-6D, and 7A-7D. As shown in FIG. 8C, the metal layer has a pitch 845, i.e., the center-to-center distance between a metal line 815 and a metal line 840 that is adjacent to the metal line 815. The pitch 845 may be between about 15 nm and 24 nm. In an example, the pitch 845 is 18 nm. In some embodiments, the pitch 845 may be about half of the pitch 417, 531, or 631. In some embodiments, the pitch 845 is at least half of the width of the metal cut 450 in FIG. 4 along the Y axis. In some embodiments, the pitch 845 is under 20 nm.

The serial DSA processes can also facilitate formation of metal cuts in the metal lines 815. At least one of the metal lines 815 may be associated with a metal cut, such as the metal cut in FIG. 1A or the metal cut 450 in FIG. 4D. The metal cut may be formed after the metal lines 815 are formed based on a first DSA process (e.g., the DSA process in FIGS. 2A-2D or the DSA process in FIGS. 3A-3D) and before the metal lines 840 are formed based on a second DSA process (e.g., the DSA process in FIGS. 5A-5D, FIGS. 6A-6D, or FIGS. 7A-7D). As the metal layer has a larger pitch before the metal lines 840 are formed, there can be more space available to facilitate the formation of the metal cut.

Further, the self-assembly of the diblock copolymers may facilitate formation of smooth surfaces of the metal lines 815 and 840, which can reduce resistances of the metal lines 815 and 840. FIG. 8D shows a structure 850, which may be a patterned structure. The structure 850 may be one of the metal lines 815 or one of the metal lines 840 in FIG. 8C. The structure 850 has two edges 853A and 853B. The edges 853A and 853B are not straight lines, meaning they are rough instead of being perfectly smooth. The edge 853A has a mean straight line 855A. The edge 853B has a mean straight line 855B. The mean straight lines 855 and 855B may be ideal (e.g., perfectly smooth) edges of the structure 850. In some embodiments, the mean straight line 855A or 855B may be determined by determining a mean X coordinate of the X coordinates of a number of points on the edge 853A or 853B. A line edge roughness may be determined for each edge.

In some embodiments, the line edge roughness may be the largest deviation from the mean straight line. As shown in FIG. 8D, the edge 853A has a line edge roughness 857A, which is the largest deviation of the edge 853A from the mean straight line 855A along the X axis, i.e., the distance from the point on the edge 853A that is furthest from the mean straight line 855A to the mean straight line 855A. The edge 853B has a line edge roughness 857B, which is the largest deviation of the edge 853B from the mean straight line 855B along the X axis, i.e., the distance from the point on the edge 853B that is furthest from the mean straight line 855A to the mean straight line 855B. The line edge roughness 857A or 857B may be between about 1.1 nm and 1.5 nm. In an example, the line edge roughness 857A or 857B may be about 1.2 nm. That is lower than line edge roughness of conventional metal lines, which can be between about 1.7 nm to 2 nm. As the surfaces of the metal lines 815 and 840 are smoother, the resistance of the metal lines 815 and 840 can be lower.

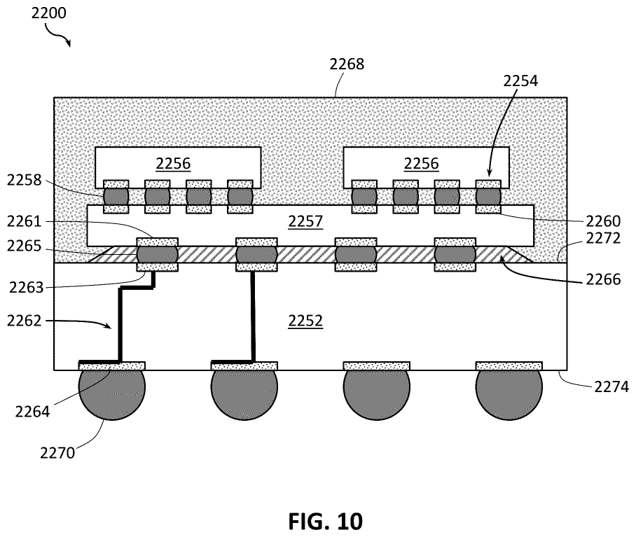

FIGS. 9A-9B are top views of a wafer 2000 and dies 2002 that may include metal lines formed through serial DSA processes, according to some embodiments of the disclosure. In some embodiments, the dies 2002 may be included in an IC package, according to some embodiments of the disclosure. For example, any of the dies 2002 may serve as any of the dies 2256 in an IC package 2200 shown in FIG. 10. The wafer 2000 may be composed of semiconductor material and may include one or more dies 2002 having IC devices formed on a surface of the wafer 2000. Each of the dies 2002 may be a repeating unit of a semiconductor product that includes any suitable IC (e.g., ICs including metal lines formed through serial DSA processes as described herein). After the fabrication of the semiconductor product is complete (e.g., after manufacture of metal lines as described herein), the wafer 2000 may undergo a singulation process in which each of the dies 2002 is separated from one another to provide discrete “chips” of the semiconductor product. In particular, devices that include metal lines formed through serial DSA processes as disclosed herein may take the form of the wafer 2000 (e.g., not singulated) or the form of the die 2002 (e.g., singulated). The die 2002 may include one or more diodes, one or more transistors (e.g., one or more III-N transistors as described herein) as well as, optionally, supporting circuitry to route electrical signals to the III-N diodes with n-doped wells and capping layers and III-N transistors, as well as any other IC components. In some embodiments, the wafer 2000 or the die 2002 may implement an electrostatic discharge (ESD) protection device, a radio frequency front-end device, a memory device (e.g., a SRAM device), a logic device (e.g., an AND, OR, NAND, or NOR gate), or any other suitable circuit element. Multiple ones of these devices may be combined on a single die 2002.

FIG. 10 is a side, cross-sectional view of an example IC package 2200 that may include one or more IC devices having metal lines formed through serial DSA processes, according to some embodiments of the disclosure. In some embodiments, the IC package 2200 may be a system-in-package (SiP).

As shown in FIG. 10, the IC package 2200 may include a package substrate 2252. The package substrate 2252 may be formed of a dielectric material (e.g., a ceramic, a glass, a combination of organic and inorganic materials, a buildup film, an epoxy film having filler particles therein, etc., and may have embedded portions having different materials), and may have conductive pathways extending through the dielectric material between the face 2272 and the face 2274, or between different locations on the face 2272, and/or between different locations on the face 2274.

The package substrate 2252 may include conductive contacts 2263 that are coupled to conductive pathways 2262 through the package substrate 2252, allowing circuitry within the dies 2256 and/or the interposer 2257 to electrically couple to various ones of the conductive contacts 2264 (or to other devices included in the package substrate 2252, not shown).

The IC package 2200 may include an interposer 2257 coupled to the package substrate 2252 via conductive contacts 2261 of the interposer 2257, first-level interconnects 2265, and the conductive contacts 2263 of the package substrate 2252. The first-level interconnects 2265 illustrated in FIG. 10 are solder bumps, but any suitable first-level interconnects 2265 may be used. In some embodiments, no interposer 2257 may be included in the IC package 2200; instead, the dies 2256 may be coupled directly to the conductive contacts 2263 at the face 2272 by first-level interconnects 2265.

The IC package 2200 may include one or more dies 2256 coupled to the interposer 2257 via conductive contacts 2254 of the dies 2256, first-level interconnects 2258, and conductive contacts 2260 of the interposer 2257. The conductive contacts 2260 may be coupled to conductive pathways (not shown) through the interposer 2257, allowing circuitry within the dies 2256 to electrically couple to various ones of the conductive contacts 2261 (or to other devices included in the interposer 2257, not shown). The first-level interconnects 2258 illustrated in FIG. 10 are solder bumps, but any suitable first-level interconnects 2258 may be used. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

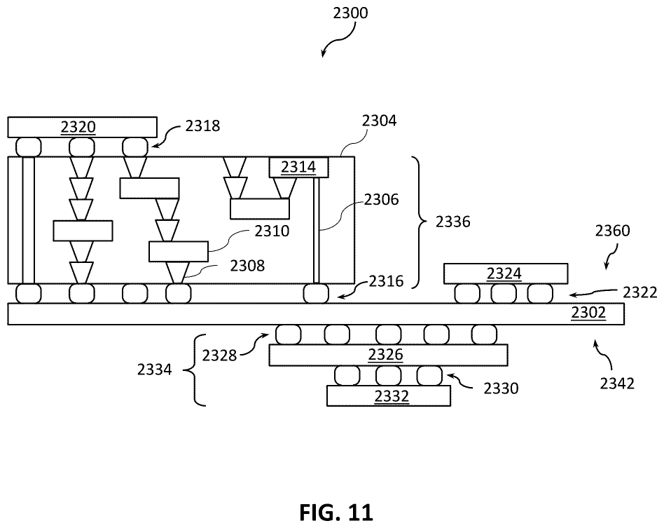

In some embodiments, an underfill material 2266 may be disposed between the package substrate 2252 and the interposer 2257 around the first-level interconnects 2265, and a mold compound 2268 may be disposed around the dies 2256 and the interposer 2257 and in contact with the package substrate 2252. In some embodiments, the underfill material 2266 may be the same as the mold compound 2268. Example materials that may be used for the underfill material 2266 and the mold compound 2268 are epoxy mold materials, as suitable. Second-level interconnects 2270 may be coupled to the conductive contacts 2264. The second-level interconnects 2270 illustrated in FIG. 10 are solder balls (e.g., for a ball grid array arrangement), but any suitable second-level interconnects 22770 may be used (e.g., pins in a pin grid array arrangement or lands in a land grid array arrangement). The second-level interconnects 2270 may be used to couple the IC package 2200 to another component, such as a circuit board (e.g., a motherboard), an interposer, or another IC package, as known in the art and as discussed below with reference to FIG. 11.

The dies 2256 may take the form of any of the embodiments of the die 2002 discussed herein and may include any of the embodiments of an IC device having metal lines formed through serial DSA processes. In embodiments in which the IC package 2200 includes multiple dies 2256, the IC package 2200 may be referred to as a multi-chip package. Importantly, even in such embodiments of an MCP implementation of the IC package 2200, metal lines formed through serial DSA processes may be provided in a single chip, in accordance with any of the embodiments described herein. The dies 2256 may include circuitry to perform any desired functionality. For example, one or more of the dies 2256 may be ESD protection dies, including metal lines formed through serial DSA processes as described herein, one or more of the dies 2256 may be logic dies (e.g., silicon-based dies), one or more of the dies 2256 may be memory dies (e.g., high bandwidth memory), etc. In some embodiments, any of the dies 2256 may include metal lines formed through serial DSA processes, e.g., metal lines as discussed above; in some embodiments, at least some of the dies 2256 may not include any III-N diodes with n-doped wells and capping layers.

The IC package 2200 illustrated in FIG. 10 may be a flip chip package, although other package architectures may be used. For example, the IC package 2200 may be a ball grid array (BGA) package, such as an embedded wafer-level ball grid array (eWLB) package. In another example, the IC package 2200 may be a wafer-level chip scale package (WLCSP) or a panel fan-out (FO) package. Although two dies 2256 are illustrated in the IC package 2200 of FIG. 10, an IC package 2200 may include any desired number of the dies 2256. An IC package 2200 may include additional passive components, such as surface-mount resistors, capacitors, and inductors disposed on the first face 2272 or the second face 2274 of the package substrate 2252, or on either face of the interposer 2257. More generally, an IC package 2200 may include any other active or passive components known in the art.

FIG. 11 is a cross-sectional side view of an IC device assembly 2300 that may include components having one or more IC devices implementing metal lines formed through serial DSA processes, according to some embodiments of the disclosure. The IC device assembly 2300 includes a number of components disposed on a circuit board 2302 (which may be, e.g., a motherboard). The IC device assembly 2300 includes components disposed on a first face 2340 of the circuit board 2302 and an opposing second face 2342 of the circuit board 2302; generally, components may be disposed on one or both faces 2340 and 2342. In particular, any suitable ones of the components of the IC device assembly 2300 may include any of the IC devices implementing metal lines formed through serial DSA processes in accordance with any of the embodiments disclosed herein; e.g., any of the IC packages discussed below with reference to the IC device assembly 2300 may take the form of any of the embodiments of the IC package 2200 discussed above with reference to FIG. 10 (e.g., may include metal lines formed through serial DSA processes in/on a die 2256).

In some embodiments, the circuit board 2302 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 2302. In other embodiments, the circuit board 2302 may be a non-PCB substrate.

The IC device assembly 2300 illustrated in FIG. 11 includes a package-on-interposer structure 2336 coupled to the first face 2340 of the circuit board 2302 by coupling components 2316. The coupling components 2316 may electrically and mechanically couple the package-on-interposer structure 2336 to the circuit board 2302, and may include solder balls (e.g., as shown in FIG. 11), male and female portions of a socket, an adhesive, an underfill material, and/or any other suitable electrical and/or mechanical coupling structure.

The package-on-interposer structure 2336 may include an IC package 2320 coupled to an interposer 2304 by coupling components 2318. The coupling components 2318 may take any suitable form for the application, such as the forms discussed above with reference to the coupling components 2316. The IC package 2320 may be or include, for example, a die (the die 2002 of FIG. 9B), an IC device (e.g., the IC device of FIGS. 1A-1B), or any other suitable component. In particular, the IC package 2320 may include metal lines formed through serial DSA processes as described herein. Although a single IC package 2320 is shown in FIG. 11, multiple IC packages may be coupled to the interposer 2304; indeed, additional interposers may be coupled to the interposer 2304. The interposer 2304 may provide an intervening substrate used to bridge the circuit board 2302 and the IC package 2320. Generally, the interposer 2304 may spread a connection to a wider pitch or reroute a connection to a different connection. For example, the interposer 2304 may couple the IC package 2320 (e.g., a die) to a BGA of the coupling components 2316 for coupling to the circuit board 2302. In the embodiment illustrated in FIG. 11, the IC package 2320 and the circuit board 2302 are attached to opposing sides of the interposer 2304; in other embodiments, the IC package 2320 and the circuit board 2302 may be attached to a same side of the interposer 2304. In some embodiments, three or more components may be interconnected by way of the interposer 2304.

The interposer 2304 may be formed of an epoxy resin, a fiberglass-reinforced epoxy resin, a ceramic material, or a polymer material such as polyimide. In some implementations, the interposer 2304 may be formed of alternate rigid or flexible materials that may include the same materials described above for use in a semiconductor substrate, such as silicon, germanium, and other group III-V and group IV materials. The interposer 2304 may include metal interconnects 2308 and vias 2310, including but not limited to TSVs 2306. The interposer 2304 may further include embedded devices 2314, including both passive and active devices. Such devices may include, but are not limited to, capacitors, decoupling capacitors, resistors, inductors, fuses, diodes, transformers, sensors, ESD protection devices, and memory devices. More complex devices such as further RF devices, power amplifiers, power management devices, antennas, arrays, sensors, and microelectromechanical systems (MEMS) devices may also be formed on the interposer 2304. In some embodiments, the IC devices implementing metal lines formed through serial DSA processes as described herein may also be implemented in/on the interposer 2304. The package-on-interposer structure 2336 may take the form of any of the package-on-interposer structures known in the art.

The IC device assembly 2300 may include an IC package 2324 coupled to the first face 2340 of the circuit board 2302 by coupling components 2322. The coupling components 2322 may take the form of any of the embodiments discussed above with reference to the coupling components 2316, and the IC package 2324 may take the form of any of the embodiments discussed above with reference to the IC package 2320.

The IC device assembly 2300 illustrated in FIG. 11 includes a package-on-package structure 2334 coupled to the second face 2342 of the circuit board 2302 by coupling components 2328. The package-on-package structure 2334 may include an IC package 2326 and an IC package 2332 coupled together by coupling components 2

such that the IC package 2326 is disposed between the circuit board 2302 and the IC package 2332. The coupling components 2328 and 2330 may take the form of any of the embodiments of the coupling components 2316 discussed above, and the IC packages 2326 and 2332 may take the form of any of the embodiments of the IC package 2320 discussed above. The package-on-package structure 2334 may be configured in accordance with any of the package-on-package structures known in the art.

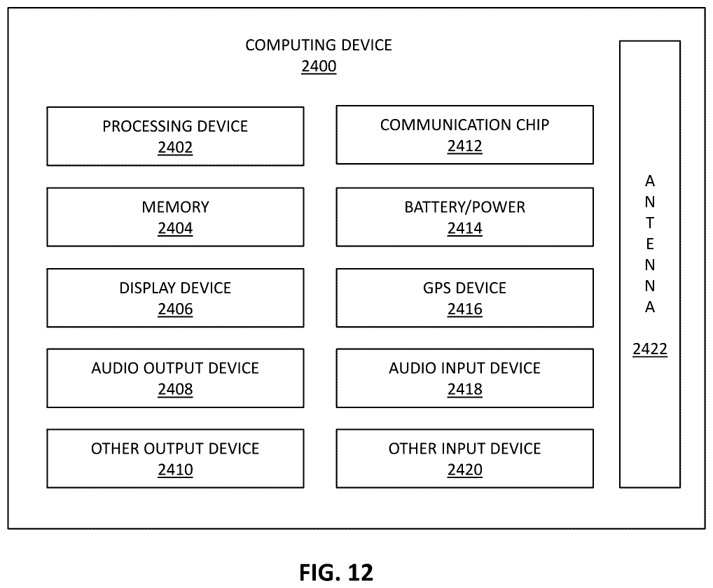

FIG. 12 is a block diagram of an example computing device 2400 that may include one or more components with one or more IC devices having metal lines formed through serial DSA processes, according to some embodiments of the disclosure. For example, any suitable ones of the components of the computing device 2400 may include a die (e.g., the die 2002 of FIG. 9B) including metal lines formed through serial DSA processes, according to some embodiments of the disclosure. Any of the components of the computing device 2400 may include an IC device (e.g., the IC device in FIGS. 1A and 1B) and/or an IC package (e.g., the IC package 2200 of FIG. 10). Any of the components of the computing device 2400 may include an IC device assembly (e.g., the IC device assembly 2300 of FIG. 11).

A number of components are illustrated in FIG. 12 as included in the computing device 2400, but any one or more of these components may be omitted or duplicated, as suitable for the application. In some embodiments, some or all of the components included in the computing device 2400 may be attached to one or more motherboards. In some embodiments, some or all of these components are fabricated onto a single SoC (system-on-chip) die.

Additionally, in various embodiments, the computing device 2400 may not include one or more of the components illustrated in FIG. 12, but the computing device 2400 may include interface circuitry for coupling to the one or more components. For example, the computing device 2400 may not include a display device 2406, but may include display device interface circuitry (e.g., a connector and driver circuitry) to which a display device 2406 may be coupled. In another set of examples, the computing device 2400 may not include an audio input device 2418 or an audio output device 2408, but may include audio input or output device interface circuitry (e.g., connectors and supporting circuitry) to which an audio input device 2418 or audio output device 2408 may be coupled.

The computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 2402 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices. The computing device 2400 may include a memory 2404, which may itself include one or more memory devices such as volatile memory (e.g., DRAM), nonvolatile memory (e.g., read-only memory (ROM)), flash memory, solid-state memory, and/or a hard drive. In some embodiments, the memory 2404 may include memory that shares a die with the processing device 2402. This memory may be used as cache memory and may include, e.g., eDRAM, and/or spin transfer torque magnetic random-access memory (STT-MRAM).

In some embodiments, the computing device 2400 may include a communication chip 2412 (e.g., one or more communication chips). For example, the communication chip 2412 may be configured for managing wireless communications for the transfer of data to and from the computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 2412 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 2412 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 2412 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2412 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 2412 may operate in accordance with other wireless protocols in other embodiments. The computing device 2400 may include an antenna 2422 to facilitate wireless communications and/or to receive other wireless communications (such as AM or FM radio transmissions).

In some embodiments, the communication chip 2412 may manage wired communications, such as electrical, optical, or any other suitable communication protocols (e.g., the Ethernet). As noted above, the communication chip 2412 may include multiple communication chips. For instance, a first communication chip 2412 may be dedicated to shorter-range wireless communications such as Wi-Fi or Bluetooth, and a second communication chip 2412 may be dedicated to longer-range wireless communications such as global positioning system (GPS), EDGE, GPRS, CDMA, WiMAX, LTE, EV-DO, or others. In some embodiments, a first communication chip 2412 may be dedicated to wireless communications, and a second communication chip 2412 may be dedicated to wired communications.

In various embodiments, IC devices as described herein may be particularly advantageous for use as part of ESD circuits protecting power amplifiers, low-noise amplifiers, filters (including arrays of filters and filter banks), switches, or other active components. In some embodiments, IC devices as described herein may be used in PMICs, e.g., as a rectifying diode for large currents. In some embodiments, IC devices as described herein may be used in audio devices and/or in various input/output devices.

The computing device 2400 may include battery/power circuitry 2414. The battery/power circuitry 2414 may include one or more energy storage devices (e.g., batteries or capacitors) and/or circuitry for coupling components of the computing device 2400 to an energy source separate from the computing device 2400 (e.g., AC line power).

The computing device 2400 may include a display device 2406 (or corresponding interface circuitry, as discussed above). The display device 2406 may include any visual indicators, such as a heads-up display, a computer monitor, a projector, a touchscreen display, a liquid crystal display (LCD), a light-emitting diode display, or a flat panel display, for example.

The computing device 2400 may include an audio output device 2408 (or corresponding interface circuitry, as discussed above). The audio output device 2408 may include any device that generates an audible indicator, such as speakers, headsets, or earbuds, for example.

The computing device 2400 may include an audio input device 2418 (or corresponding interface circuitry, as discussed above). The audio input device 2418 may include any device that generates a signal representative of a sound, such as microphones, microphone arrays, or digital instruments (e.g., instruments having a musical instrument digital interface (MIDI) output).

The computing device 2400 may include a GPS device 2416 (or corresponding interface circuitry, as discussed above). The GPS device 2416 may be in communication with a satellite-based system and may receive a location of the computing device 2400, as known in the art.

The computing device 2400 may include an other output device 2410 (or corresponding interface circuitry, as discussed above). Examples of the other output device 2410 may include an audio codec, a video codec, a printer, a wired or wireless transmitter for providing information to other devices, or an additional storage device.

The computing device 2400 may include an other input device 2420 (or corresponding interface circuitry, as discussed above). Examples of the other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 2400 may be any other electronic device that processes data.

The following paragraphs provide various examples of the embodiments disclosed herein.

Example 1 provides an IC device, including a first layer, including a first conductive structure, a first portion of a second conductive structure that is in parallel with the first conductive structure, and an electrical insulator between the first conductive structure and the first portion of the second conductive structure; and a second layer over the first layer, the second layer including a second portion of the second conductive structure, and an insulative structure, including a first insulative structure and a second insulative structure at least partially surrounding the first insulative structure, where a portion of the insulative structure is over the first conductive structure in a direction, and an axis of the insulative structure in the direction is aligned with an axis of the first conductive structure in the direction.

Example 2 provides the IC device according to example 1, where the first layer further comprises a third conductive structure, the first portion of the second conductive structure is between the first conductive structure and the third conductive structure in a first direction, the first conductive structure comprising a first portion and a second portion that are separated from each other by at least part of a third insulative structure, and a distance between a center of the first conductive structure and a center of the third conductive structure in a first direction is equal to or greater than a dimension of the third insulative structure in a second direction, the first direction is perpendicular to the direction, and the second direction is perpendicular to the direction and to the first direction.

Example 3 provides the IC device according to example 2, where the third conductive structure comprising a third portion and a fourth portion that are separated from each other by at least part of the third insulative structure.

Example 4 provides the IC device according to example 2 or 3, where a distance between the center of the first conductive structure and a center of the second conductive structure in the first direction is approximately half of the distance between the center of the first conductive structure and the center of the third conductive structure in the first direction.

Example 5 provides the IC device according to any one of examples 2-4, where a dimension of the third insulative structure in the direction, which is perpendicular to the first direction and the second direction, is the same or substantially the same as a dimension of the first conductive structure in the direction.

Example 6 provides the IC device according to any of the preceding examples, where a line edge roughness of a surface of the first conductive structure or the second conductive structure is between about 1.1 and 1.5 nanometers.

Example 7 provides the IC device according to example 5, where the line edge roughness of the surface of the first conductive structure or the second conductive structure is about 1.2 nanometer.

Example 8 provides the IC device according to any of the preceding examples, where a distance from a center of the first conductive structure to a center of the second conductive structure in another direction perpendicular to the direction is no greater than 20 nanometers.

Example 9 provides the IC device according to any of the preceding examples, where the first conductive structure includes a different metal from the second conductive structure.

Example 10 provides the IC device according to any of the preceding examples, where the first conductive structure or the second conductive structure is connected to a first end of a via, a second end of the via is connected to an electrode of a transistor, and the first layer is between the transistor and the second layer.

Example 11 provides an IC device, including a plurality of structures, an individual structure including a first structure including a first electrical insulator, a second structure including a second electrical insulator and at least partially surrounding the first structure, and a third structure over at least part of the first structure in a direction, the third structure including an electrically conductive material; and a plurality of conductive structures that are in parallel with the plurality of structures, individual conductive structures alternating with individual structures, where a dimension of an individual conductive structure in the direction is the same or substantially the same as a dimension of the individual structure in the direction.

Example 12 provides the IC device according to example 11, where the third structure includes a first portion and a second portion that are separated from each other by an insulative structure, a distance between two adjacent structures in a first direction is equal to or greater than a dimension of the insulative structure in a second direction, the first direction is perpendicular to the direction, and the second direction is perpendicular to the direction and to the first direction.

Example 13 provides the IC device according to example 11 or 12, where a line edge roughness of a surface of the third structure or the individual conductive structure is between about 1.1 and 1.5 nanometers.

Example 14 provides a method for forming an IC device, including forming a first lamellar pattern over a surface of a conductive layer by applying a first diblock copolymer in a first lamellar phase to the surface of the conductive layer, the first lamellar pattern including first lamellar structures alternating with second lamella structures; forming, from the conductive layer, a plurality of first conductive structures based on the first lamellar pattern; forming a first layer, the first layer including the plurality of first conductive structures and an electrical insulator, the plurality of first conductive structures separated from each other by a plurality of portions of the electrical insulator; forming a second lamellar pattern over a surface of the first layer by applying a second diblock copolymer in a second lamellar phase to the surface of the first layer, the second lamellar pattern including third lamellar structures alternating with fourth lamella structures; forming a plurality of insulative structures over the surface of the first layer based on the second lamellar pattern, the plurality of insulative structures separated from each other; and forming a plurality of second conductive structures, an individual second conductive structure between two adjacent insulative structures.

Example 15 provides the method according to example 14, where an axis of an individual first conductive structure is aligned with an axis of an individual insulative structure.

Example 16 provides the method according to example 14 or 15, where forming a plurality of insulative structures over the surface of the first layer based on the second lamellar pattern includes forming a plurality of third insulative structures over the surface of the first layer based on the second lamellar pattern, a position of an individual third insulative structure on the surface of the first layer matching a position of an individual third lamellar structure on the surface of the first layer; and forming a plurality of fourth insulative structures, an individual fourth insulative structure wrapping around at least part of the individual third insulative structure, where the individual second conductive structure includes the individual third insulative structure and the individual fourth insulative structure.

Example 17 provides the method according to any one of examples 14-16, further including before forming the second lamellar pattern over the surface of the first layer, forming an opening in an individual first conductive structure; and filling the opening with a third insulative structure.

Example 18 provides the method according to example 17, where the axis of the first conductive structure is along a first direction, and a dimension of the third insulative structure in a second direction perpendicular to the first direction is not greater than a distance between the two adjacent first conductive structures in a third direction perpendicular to the first direction and the second direction.

Example 19 provides the method according to any one of examples 14-18, where forming the plurality of second conductive structures including forming a plurality of openings based on a pattern of the plurality of insulative structures, where an individual opening is between two adjacent insulative structures, and a portion of the individual opening is in the first layer; and forming the plurality of second conductive structures in the plurality of openings.

Example 20 provides the method according to any one of examples 14-19, where an individual third lamellar structure is over an individual first conductive structure, and an individual fourth lamellar structure is over an individual portion of the electrical insulator.

Example 21 provides an IC package, including the IC device according to any one of examples 1-13; and a further IC component, coupled to the device.

Example 22 provides the IC package according to example 21, where the further IC component includes one of a package substrate, an interposer, or a further IC die.

Example 23 provides the IC package according to example 21 or 22, where the IC device according to any one of examples 1-15 may include, or be a part of, at least one of a memory device, a computing device, a wearable device, a handheld electronic device, and a wireless communications device.

Example 24 provides an electronic device, including a carrier substrate; and one or more of the IC devices according to examples 1-13 and the IC package according to any one of examples 21-23, coupled to the carrier substrate.

Example 25 provides the electronic device according to example 24, where the carrier substrate is a motherboard.

Example 26 provides the electronic device according to example 24, where the carrier substrate is a PCB.

Example 27 provides the electronic device according to any one of examples 24-26, where the electronic device is a wearable electronic device or handheld electronic device.

Example 28 provides the electronic device according to any one of examples 24-27, where the electronic device further includes one or more communication chips and an antenna.

Example 29 provides the electronic device according to any one of examples 24-28, where the electronic device is an RF transceiver.

Example 30 provides the electronic device according to any one of examples 24-28, where the electronic device is one of a switch, a power amplifier, a low-noise amplifier, a filter, a filter bank, a duplexer, an upconverter, or a downconverter of an RF communications device, e.g., of an RF transceiver.

Example 31 provides the electronic device according to any one of examples 24-30, where the electronic device is a computing device.

Example 32 provides the electronic device according to any one of examples 24-31, where the electronic device is included in a base station of a wireless communication system.

Example 33 provides the electronic device according to any one of examples 24-31, where the electronic device is included in a user equipment device of a wireless communication system.

Example 34 provides the method according to any one of examples 14-20, further including processes for forming the IC device according to any one of claims 1-13.

Example 35 provides the method according to any one of examples 14-20, further including processes for forming the IC package according to any one of the claims 21-23.

Example 36 provides the method according to any one of examples 14-20, further including processes for forming the electronic device according to any one of the claims 24-33.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An integrated circuit (IC) device, comprising:
a first layer, comprising:
a first conductive structure,
a first portion of a second conductive structure that is in parallel with the first conductive structure, and
an electrical insulator between the first conductive structure and the first portion of the second conductive structure; and
a second layer over the first layer, the second layer comprising:
a second portion of the second conductive structure, and
an insulative structure comprising a first insulative structure and a second insulative structure, the second insulative structure at least partially surrounding the first insulative structure,
wherein a portion of the insulative structure is over the first conductive structure in a direction, and an axis of the insulative structure in the direction is aligned with an axis of the first conductive structure in the direction.

2. The IC device according to claim 1, wherein:
the first layer further comprises a third conductive structure,
the first portion of the second conductive structure is between the first conductive structure and the third conductive structure in a first direction,
the first conductive structure comprising a first portion and a second portion that are separated from each other by at least part of a third insulative structure,
a distance between a center of the first conductive structure and a center of the third conductive structure in the first direction is equal to or greater than a dimension of the third insulative structure in a second direction,
the first direction is perpendicular to the direction, and
the second direction is perpendicular to the direction and to the first direction.

3. The IC device according to claim 2, wherein the third conductive structure comprising a third portion and a fourth portion that are separated from each other by at least part of the third insulative structure.

4. The IC device according to claim 2, wherein a distance between the center of the first conductive structure and a center of the second conductive structure in the first direction is approximately half of the distance between the center of the first conductive structure and the center of the third conductive structure in the first direction.

5. The IC device according to claim 2, wherein a dimension of the third insulative structure in the direction is the same or substantially the same as a dimension of the first conductive structure in the direction.

6. The IC device according to claim 1, wherein a line edge roughness of a surface of the first conductive structure or the second conductive structure is between about 1.1 and 1.5 nanometers.

7. The IC device according to claim 5, wherein the line edge roughness of the surface of the first conductive structure or the second conductive structure is about 1.2 nanometer.

8. The IC device according to claim 1, wherein a distance from a center of the first conductive structure to a center of the second conductive structure in another direction perpendicular to the direction is no greater than 20 nanometers.

9. The IC device according to claim 1, wherein the first conductive structure comprises a different metal from the second conductive structure.

10. The IC device according to claim 1, wherein the first conductive structure or the second conductive structure is connected to a first end of a via, a second end of the via is connected to an electrode of a transistor, and the first layer is between the transistor and the second layer.

11. An integrated circuit (IC) device, comprising:
a plurality of structures, an individual structure comprising:
a first structure comprising a first electrical insulator,
a second structure comprising a second electrical insulator and at least partially surrounding the first structure, and
a third structure over at least part of the first structure in a direction, the third structure comprising an electrically conductive material; and
a plurality of conductive structures that are in parallel with the plurality of structures, individual conductive structures alternating with individual structures,
wherein a dimension of an individual conductive structure in the direction is the same or substantially the same as a dimension of the individual structure in the direction.

12. The IC device according to claim 11, wherein:
the third structure comprises a first portion and a second portion that are separated from each other by an insulative structure,
a distance between two adjacent structures in a first direction is equal to or greater than a dimension of the insulative structure in a second direction,
the first direction is perpendicular to the direction, and
the second direction is perpendicular to the direction and to the first direction.

13. The IC device according to claim 11, wherein a line edge roughness of a surface of the third structure or the individual conductive structure is between about 1.1 and 1.5 nanometers.

14. A method for forming an integrated circuit (IC) device, comprising:
forming a first lamellar pattern over a surface of a conductive layer by applying a first diblock copolymer in a first lamellar phase to the surface of the conductive layer, the first lamellar pattern comprising first lamellar structures alternating with second lamella structures;
forming, from the conductive layer, a plurality of first conductive structures based on the first lamellar pattern;
forming a first layer, the first layer comprising the plurality of first conductive structures and an electrical insulator, the plurality of first conductive structures separated from each other by a plurality of portions of the electrical insulator;
forming a second lamellar pattern over a surface of the first layer by applying a second diblock copolymer in a second lamellar phase to the surface of the first layer, the second lamellar pattern comprising third lamellar structures alternating with fourth lamella structures;
forming a plurality of insulative structures over the surface of the first layer based on the second lamellar pattern, the plurality of insulative structures separated from each other; and
forming a plurality of second conductive structures, an individual second conductive structure between two adjacent insulative structures.

15. The method according to claim 14, wherein an axis of an individual first conductive structure is aligned with an axis of an individual insulative structure.

16. The method according to claim 14, wherein forming a plurality of insulative structures over the surface of the first layer based on the second lamellar pattern comprises:
forming a plurality of third insulative structures over the surface of the first layer based on the second lamellar pattern, a position of an individual third insulative structure on the surface of the first layer matching a position of an individual third lamellar structure on the surface of the first layer; and
forming a plurality of fourth insulative structures, an individual fourth insulative structure wrapping around at least part of the individual third insulative structure,
wherein the individual second conductive structure comprises the individual third insulative structure and the individual fourth insulative structure.

17. The method according to claim 14, further comprising:
before forming the second lamellar pattern over the surface of the first layer, forming an opening in an individual first conductive structure; and
filling the opening with a third insulative structure.

18. The method according to claim 17, wherein:
the axis of the first conductive structure is along a first direction, and
a dimension of the third insulative structure in a second direction perpendicular to the first direction is not greater than a distance between the two adjacent first conductive structures in a third direction perpendicular to the first direction and the second direction.

19. The method according to claim 14, wherein forming the plurality of second conductive structures comprising:
forming a plurality of openings based on a pattern of the plurality of insulative structures, wherein an individual opening is between two adjacent insulative structures, and a portion of the individual opening is in the first layer; and
forming the plurality of second conductive structures in the plurality of openings.

20. The method according to claim 14, wherein an individual third lamellar structure is over an individual first conductive structure, and an individual fourth lamellar structure is over an individual portion of the electrical insulator.
